(19) United States
(12) Patent Application Publication
(10) Pub. No.: US 2013/0280854 A1
(43) Pub. Date: Oct. 24, 2013

(54) SINTERED DEVICE

(71) Applicants: Jacek Jasieniak, Australian Capital Territory (AU); Brandon MacDonald, Somerville, MA (US); Paul Mulvaney, Victoria (AU)

(72) Inventors: Jacek Jasieniak, Australian Capital Territory (AU); Brandon MacDonald, Somerville, MA (US); Paul Mulvaney, Victoria (AU)

(73) Assignees: THE UNIVERSITY OF MELBOURNE; COMMONWEALTH SCIENTIFIC AND INDUSTRIAL RESEARCH ORGANISATION

(21) Appl. No.: 13/877,881

(22) PCT Filed: Oct. 5, 2011
(86) PCT No.: PCT/AU11/01264

§ 371 Date: Jul. 3, 2013

(30) Foreign Application Priority Data
Oct. 5, 2010 (AU) 2010904464

(51) Int. Cl. H01L 31/18

(52) U.S. Cl. CPC H01L 31/18
USPC 438/93

(57) ABSTRACT

A method for the production of an inorganic film on a substrate, the method comprising: (a) depositing a layer of nanoparticles on the substrate by contacting the substrate with a nanoparticle dispersion; (b) treating the deposited layer of nanoparticles to prevent removal of the nanoparticles in subsequent layer depositing steps; (c) depositing a further layer of nanoparticles onto the preceding nanoparticle layer on the substrate; (d) repeating treatment step (b) and deposition step (c) at least one further time; and (e) optionally thermally annealing the multilayer film produced following steps (a) to (d); wherein the method comprises at least one thermal annealing step in which the layer or layers of nanoparticles are thermally annealed.

### FIELD

The present invention relates generally to electronic devices containing inorganic films of sintered nanoparticles, such as solar cells. The present invention also relates to methods for the production of such inorganic films on substrates, for the manufacture of such electronic devices.

### BACKGROUND

A number of electronic devices contain inorganic films which provide electrical activity in the device. As one example, inorganic solar cells contain active inorganic material films of a charge accepting and a charge transporting material.

Electronic devices such as solar cells and light-emitting diodes are typically manufactured by vacuum deposition of the active inorganic material film onto a substrate. Vacuum deposition involves depositing layers of particles onto the substrate at sub-atmospheric pressures.

Another method for depositing particles onto a substrate involves a technique known as solution processing or solution deposition. Producing a device through solution deposition of inorganic particles onto a substrate involves the deposition of a single layer of nanoparticles (or “nanocrystals”) onto the substrate to produce a single layer (or film) of that material on the substrate. The same process may be used to deposit a single layer of a second material to produce a bilayer film on the substrate. The entire substrate is then chemically treated and thermally annealed to induce crystal growth (or “grain growth”). A disadvantage of this single layer deposition approach is the formation of cracks and pinholes during the chemical treatment and the thermal annealing processes. In the case of electronic devices, the presence of cracks and pinholes can allow two electrodes to come into direct contact and create a short-circuit. Accordingly, a lower quality device results.

This problematic occurrence of cracks and pinholes arises due to stresses that develop within the film as it contracts during either ligand exchange or during grain growth. The effects of stress induced changes to nanocrystal films is one of the major limitations of single layer deposition of nanocrystals if chemical and thermal treatments are required.

In addition, solution processing typically leads to thinner devices than those which can be achieved through vacuum deposition. Thinner devices tend to absorb less light, a drawback that is particularly significant for solar cells.

Accordingly, it is difficult to produce a sufficiently thick film of nanoparticles using single layer deposition and if a film of sufficient thickness can be achieved, stress induced cracks and pinholes limit the utility of devices comprising the film. It is therefore an object of the present invention to address some of these problems.

### SUMMARY OF THE INVENTION

The method of the present invention enables the fabrication of inorganic films having fewer defects compared with other solution-based methods. The films may also exhibit higher charge mobility.

According to a first embodiment, there is provided a method for the production of an inorganic film on a substrate, the method comprising:
(a) depositing a layer of nanoparticles on the substrate by contacting the substrate with a nanoparticle dispersion;
(b) treating the deposited layer of nanoparticles to prevent removal of the nanoparticles in subsequent layer depositing steps;
(c) depositing a further layer of nanoparticles onto the preceding nanoparticle layer on the substrate;
(d) repeating treatment step (b) and deposition step (c) at least one further time; and
(e) optionally thermally annealing the multilayer film produced following steps (a) to (d),
   wherein the method comprises at least one thermal annealing step in which the layer or layers of nanoparticles are thermally annealed.

In another embodiment, there is also provided a method for the production of an inorganic film on a substrate, the method comprising:
(a) depositing a layer of nanoparticles on the substrate by contacting the substrate with a nanoparticle dispersion;
(b) treating the deposited layer of nanoparticles to prevent removal of the nanoparticles in subsequent layer depositing steps;
(c) depositing a further layer of nanoparticles onto the preceding nanoparticle layer on the substrate; and
(d) repeating treatment step (b) and deposition step (c) at least one further time;
   wherein the method comprises at least one thermal annealing step in which the layer or layers of nanoparticles are thermally annealed.

In one embodiment, the multilayer film produced following steps (a) to (d) is thermally annealed.

There is also provided an inorganic film produced by the above method. The present invention also provides an inorganic film obtainable by the above method.

The thermal annealing step creates crystallisation between particles in adjacent layers of the film. Thus according to a second embodiment of the invention there is provided an electronic device comprising:
an anode;
a cathode; and
at least one multilayered film of an inorganic material, wherein the multilayered film of an inorganic material contains crystallisation between particles in adjacent layers of the film.

According to a third embodiment there is provided a solar cell comprising:
an anode;
a cathode; and
an active material film positioned between the anode and the cathode;
   wherein the active material film comprises a multilayered film of an inorganic material, and the multilayered film of inorganic material contains crystallisation between particles in adjacent layers of the film.

The active material film may comprise a charge accepting film and a charge transport film, thus, in a fourth embodiment the solar cell comprises:
an anode;
a cathode; and
a charge accepting film and a charge transport film positioned between the anode and the cathode;
   wherein at least one of the charge accepting film and charge transport film is a multilayered film of an inorganic material, wherein the multilayered film of an inorganic material contains crystallisation between particles in adjacent layers of the film.

One of the perceived difficulties of making a thicker film by multiple layering of nanoparticles is that the chemical treatment and/or thermal annealing steps will result in the formation of cracks and pinholes which will prevent the use of the film in electronic devices due to short-circuiting. However, it has been found that by treating the layers of nanoparticles between deposition steps, it is possible to avoid these problems. It has also been found that by producing a film in this way, it is possible to produce an electronic device with power conversion efficiencies greater than achieved before.

Thus, in a fifth embodiment, there is provided a solar cell comprising:
an anode;
a cathode; and
a charge accepting film and a charge transport film positioned between the anode and the cathode;
   wherein at least one of the charge accepting film and charge transport film is a multilayered film of an inorganic material, wherein the multilayered film of an inorganic material contains crystallisation between particles in adjacent layers of the film, and wherein the solar cell has a power conversion efficiency of at least 4%.

According to a sixth embodiment, there is also provided a method for the production of a solar cell, the method comprising:
(i) producing a charge accepting film on a substrate according to the method described above, wherein the substrate is an anode; and
(ii) coupling the product of step (i) with a charge transport film and a cathode to produce a solar cell.

### BRIEF DESCRIPTION OF THE DRAWINGS

The invention will be described in further detail with reference to the following figures.

FIG. 1 is a schematic representation of the method of one embodiment.

FIG. 2 shows thermogravimetric analysis (TGA), performed in air, of CdTe nanoparticles with oleic acid, tri-n-octylphosphine/tri-n-octylphosphine oxide and pyridine surface chemistries and the TGA of initially pyridine over-coated CdTe nanoparticles following CdCl₂ treatment, including one (a) showing relative mass loss as a function of temperature and a second (b) showing the rate of mass loss as a function of temperature.

FIG. 3 is a graph showing the absorption spectra (absorbance v wavelength) of CdTe films according to embodiments thermally annealed at different temperatures without CdCl₂ chemical treatment (curves are offset for clarity).

FIG. 4 is a graph showing the absorption spectra (absorbance v wavelength) of CdTe films according to embodiments annealed at different temperatures after exposure to CdCl₂ chemical treatment(curves are offset for clarity).

FIG. 5 is a graph showing the absorption spectra (absorbance v wavelength) of a CdTe film which has been treated by spin-casting a 5 mg/mL solution of CdCl₂ on top of the CdTe followed by annealing.

FIG. 6 is a graph showing absorbance at 400 nm v time for CdTe films according to embodiments thermally annealed at different temperatures, with and without CdCl₂ exposure.

FIG. 7 is a graph showing X-ray diffraction spectra (intensity v degrees) for CdTe films according to embodiments: as-cast (squares), thermally annealed at 350° C. (circles), and chemically treated with CdCl₂ then thermally annealed at 350° C. (triangles). Average crystal sizes are approximately 4 nm, 19 nm and 68 nm respectively.

FIG. 8 is a graph showing an X-ray diffraction spectrum (intensity v degrees) of a ZnO film according to an embodiment thermally annealed at 300° C. Average crystal size is 8 nm.

FIG. 9 shows atomic force microscopy (AFM) images for three CdTe films including one (a) which comprises a single layer of CdTe film. a second (b) which comprises a four layer CdTe film which has been treated with CdCl₂ and thermally annealed after every layer and a third (c) which comprises a four layer CdTe film which has been over-coated with ZnO.

FIG. 10 is a graph showing J-V curve (current density v voltage) of a CdTe/CdSe nanorod device in which the cell was thermally annealed in a single step after all semiconducting layers had been deposited.

FIG. 11 is a graph showing J-V curves (current density v voltage) for a CdTe-only device (triangles), as well as CdTe/CdSe (diamonds), CdTe/CdS (circles) and CdTe/ZnO (squares) device structures.

FIG. 12 shows flatband energy level diagrams including one (a) of all components within an ITO/CdTe/ZnO/Al solar cell according to one embodiment, a second (b) of the electronic structure following ideal contact between each layer and a third (c) when the CdTe is fully depleted.

FIG. 13 is a graph showing J-V curves (current density v voltage) for CdTe/ZnO devices according to embodiments with varying annealing temperatures for the CdTe layers. In all devices the ZnO was thermally annealed at 150° C.

FIG. 14 is a graph showing J-V curves (current density v voltage) for CdTe-only devices according to embodiments with varying thermal annealing temperatures.

FIG. 15 shows scanning electron micrographs of two completed CdTe/ZnO devices with ITO and aluminium electrodes, including one (a) showing the morphology of devices made with only thermal treatment (i.e. no chemical treatment step) on the CdTe layers, and a second (b) showing the full extent of grain growth within the CdTe layer following both chemical treatment and thermal annealing steps.

FIG. 16 is a graph showing J-V curves (current density v voltage) in which the CdTe layers have been annealed at 300° C. for differing times. The inset box describes the power conversion efficiencies of devices annealed at 300° C. as a function of annealing time per layer.

FIG. 17 is a graph showing J-V curves (current density v voltage) in which the CdTe layers have been annealed at 350° C. for differing times. The inset box describes the power conversion efficiencies of devices annealed at 350° C. as a function of annealing time per layer.

FIG. 18 is a graph showing J-V curves (current density v voltage) in which the CdTe layers have been annealed at 400° C. for differing times. The inset box describes the power conversion efficiencies of devices annealed at 400° C. as a function of annealing time per layer.

FIG. 19 is a graph showing J-V curves (current density v voltage) for cells in which the CdCl₂ treatment has been applied by dipping the CdTe films into a saturated CdCl₂ solution in methanol then rinsing with 1-propanol and where the CdCl₂ has been spin cast onto the CdTe from a 5 mg/mL solution in methanol.

FIG. 20 is a graph showing the absorption spectra (absorbance v wavelength) of CdTe films treated with various metal chlorides and annealed at 350° C.

FIG. 21 is a graph showing J-V curves (current density v voltage) of CdTe/ZnO solar cells in which the CdTe layers were treated with various metal chlorides.

FIG. 22 is a graph showing IPCE curves (incident photon conversion efficiency v wavelength) for devices according to embodiments in which the CdTe layers have been thermally annealed at 350° C. for different times.

FIG. 23 is a graph showing J-V curves (current density v voltage) for devices according to embodiments with four CdTe layers which have been thermally annealed: after every layer (diamonds), after the second and fourth layers (circles) and after all four layers, that is, only a single annealing step (triangles).

FIG. 24 is a graph showing J-V curves (current density v voltage) for a CdTe/ZnO solar cell annealed to various temperatures following deposition of the back Al contact.

FIG. 25 is a graph showing J-V curves (current density v voltage) for solar cells where all layers were annealed in air (squares), CdTe layers were annealed in N₂, following by ZnO annealing in air (triangles), CdTe layers annealed in N₂ then air after the final CdTe layer (circles), all CdTe and ZnO layers in N₂ (diamonds).

FIG. 26 is a graph showing J-V curves (current density v voltage) for CdTe/ZnO devices according to embodiments with different ZnO thermal annealing temperatures. Inset: Power conversion efficiencies as a function of ZnO thermal annealing temperature.

FIG. 27 is a graph showing J-V curves (current density v voltage) for CdTe/ZnO cells in which the ZnO was prepared with different synthetic protocols, as well as with and without the addition of butylamine as a surface passivant.

FIG. 28 is a graph showing J-V curves (current density v voltage) of devices made using ZnO nanocrystals synthesized in-house (squares) and purchased commercially (circles).

FIG. 29 is graph showing J-V curves (current density v voltage) of a solar cell made using a ZnO layer made by a sol-gel process.

FIG. 30 is graph showing J-V curves (current density v voltage) for a solar cell in which the ZnO layer was sputtered on top of the CdTe (squares) and one in which the CdTe was first coated with nanocrystalline ZnO followed by sputtered ZnO (circles).

FIG. 31 is a graph showing J-V curves (current density v voltage) of devices according to embodiments with varying CdTe thickness. A 60 nm ZnO layer was deposited on top of the CdTe for all devices. The inset box describes power conversion efficiencies as a function of CdTe thickness.

FIG. 32 is a graph showing J-V curves (current density v voltage) for CdTe/Zn) solar cells with difference active device areas.

FIG. 33 is a graph showing J-V curves (current density v voltage) of CdTe/ZnO devices according to embodiments with different metal top contacts.

FIG. 34A is a is a graph showing J-V curves (current density v voltage) for a solar cell made using oleic acid capped CdTe deposited from chloroform. FIG. 34B is a graph showing J-V curves (current density v voltage) of a solar cell made from hexylamine capped CdTe deposited from chlorobenzene.

FIG. 35 is a graph showing J-V curve (current density v voltage) and performance characteristics of an inverted device with the structure ITO/ZnO/CdTe/Au.

FIG. 36 is a graph showing J-V curve (current density v voltage) for solar cells made using a substrate configuration. The CdTe layers were deposited onto Mo coated glass in a layer-by-layer method, followed by CdS and/or ZnO NCs and sputtered ITO.

FIG. 37 is a graph showing J-V curve (current density v voltage) for CdTe/CdSe/ZnO solar cells with a varying number of CdTe and CdSe layers. In all instances the total number of CdTe and CdSe layers was four.

FIG. 38A shows a tapping mode AFM image of a CdTe film which has been CdCl₂ treated and annealed at 350° C. FIG. 38B shows an AFM image of a CdSe film which has undergone the same treatment. FIG. 38C shows a cross-sectional SEM image of a CdTe/ZnO. FIG. 38D shows a cross-sectional SEM image of a CdTe(x1)/CdSe(x3)/ZnO device. Note the difference in scale bar between C and D.

FIG. 39 shows absorption spectra (absorbance v wavelength) for CdSeₓ:CdTe₍₁₋ₓ₎ solutions with varying values of x.

FIG. 40 shows X-ray diffraction spectrum (intensity v degrees) for 100 nm thick CdSeₓTe₍₁₋ₓ₎ films with varying values of x. All films were treated with CdCl₂ and annealed at 350° C. prior to measurement.

FIG. 41A shows a plot of (αhv)² versus photon energy for CdSeₓTe₍₁₋ₓ₎ alloy films.

FIG. 41B shows optical bandgap as a function of x. FIG. 41C shows PESA results for selected CdSeₓTe₍₁₋ₓ₎ compositions. Ionization energy is determined by extrapolation of the fitted straight lines to the baseline. FIG. 41D shows valence band (VB) and conduction band (CB) energy levels as a function of x.

FIG. 42A shows J-V curve (current density v voltage) for CdTe(100 nm)/CdSeₓTe₍₁₋ₓ₎ (300 nm)/ZnO/Al cells for selected x values. (B) IPCE curves for the same cells as (A).

FIG. 43A shows J-V curve (current density v voltage) for graded alloy devices in both the ‘forward’ and ‘reverse’ directions. FIG. 43B shows IPCE curves for the cells in A. FIGS. 43C and D show flat band energy levels for the layers in the ‘forward’ and ‘reverse’ graded structures respectively.

### DETAILED DESCRIPTION

The present invention relates generally to electronic devices containing inorganic films of sintered nanoparticles, such as solar cells. The present invention also relates to methods for the production of such inorganic films on substrates, for the manufacture of such electronic devices.

In the following, we have described features of the method and devices. All features described below apply independently to the methods and the devices of the invention.

To overcome limitations of the prior art, the present method utilizes a layer-by-layer method in which deposition and treatment steps are repeated multiple times.

For this type of approach to be successful, the treatment generally requires for there to be change in surface chemistry of the deposited layer or partial sintering of the layer to prevent removal of the nanoparticles in subsequent layer depositing steps. In this way, multi-layers can be deposited one on top of another without removal of the nanoparticles of previously deposited layers. This permits the cracks and pinholes that are formed during the chemical treatment and/or thermal annealing steps to be gradually over-coated. By creating inorganic films with fewer macroscopic and microscopic imperfections, efficient multilayer inorganic film solar cells can be fabricated more reproducibly and with significantly thinner layers than existing approaches.

It is an advantage that solar cells comprising the inorganic film prepared by the present method are more efficient than those prepared by the methods of the prior art. It is therefore also an advantage that the inorganic film prepared by the present method requires almost half the amount of material to provide a power conversion efficiency comparable to, or better than, that of the prior art.

### Substrate

The term substrate refers to any surface on which it is desired to build an inorganic film.

The substrate may be, as one example, an electrode or other physical structure, or the substrate may comprise a film coated on such an electrode or physical structure, this entire composition constituting the “substrate”. Thus, it will be understood that the substrate may be a single or multilayered substrate. As one example, the substrate may comprise a solid support and an electronic layer. An example of an electronic layer is an electrode layer. As another example, the substrate may comprise an electrode and an inorganic film composition on the electrode.

In one embodiment, the substrate is a transparent substrate. The substrate may be flexible (for example a flexible polymer film) or rigid (for example a rigid polymer structure, or glass). In one embodiment the substrate is glass. In yet another embodiment, the substrate is transparent substrate on which a film of a transparent conductive oxide has been deposited.

In one embodiment, the substrate on which the layer of nanoparticles is deposited in step (a) comprises a pre-deposited sol-gel layer or sol-gel produced inorganic film.

Sol-gels are well known in the art and generally refer to colloidal solutions of inorganic materials (sol) in a gel network (gel). Sol-gels have properties between liquids and solids. A sol-gel may comprise a colloid solution of inorganic material in either a particle network or a polymer network.

In the present application, the term “sol-gel produced inorganic film” refers to a film (no longer in sol-gel form) which has been produced through application of a sol-gel followed by treatment to form an inorganic film. For example, the sol-gel may be converted to an inorganic film by annealing.

Typically, the inorganic materials in the sol-gel are those described below in the context of the nanoparticles.

### Nanoparticles

The term “nanoparticle” is well understood in the art of the invention and nanoparticles are used in many different applications. In this application, the term “nanoparticle” refers generally to a particle having at least one dimension that is less than about 1000 nanometres.

The nanoparticles are typically inorganic nanoparticles. Inorganic nanoparticles of the type used herein are typically crystalline and therefore the nanoparticles may be typically referred to as “nanocrystals”.

The nanoparticles may be made of any inorganic material and may be elemental, compound or composite-based.

Preferably, the nanoparticles have a diameter of up to about 100 nanometres, more preferably up to about 10 nanometres. Preferably, the nanoparticles have a diameter of at least about 1 nanometre, more preferably at least about 4 nanometres. The nanoparticles may have a diameter in the range of about 1 nanometre to about 100 nanometres, such as about 1 nanometre to about 10 nanometres. The nanoparticles can be any shape such as spheroid or rod shaped. In some embodiments, the nanoparticles are spherical. As an example, at least about 50% of the nanoparticles are spherical, or at least about 60% of the nanoparticles are spherical, or at least about 70% of the nanoparticles are spherical.

Absorption measurements on the inorganic films of the invention can yield information about the size of the nanocrystals. Due to the quantum confinement effect, when the size of a semiconductor nanocrystal is smaller than its Bohr radius the bandgap will begin to shift to higher energies. Based on established size-versus absorption energy calibration curves, an estimate of the size from this measurement can be achieved. For sizes beyond the confinement regime, techniques such as XRD, AFM, and SEM are the preferred methods for determining size.

In one embodiment, the nanoparticles are active material-forming nanoparticles. The term active material refers to a material used in an electronic device that has electrical or optical function. Active materials include semiconductor materials (including p-type semiconductor materials and n-type semiconductor materials), light absorbing materials, charge blocking materials, charge transport materials, light emitting materials, temperature responsive materials, conductive materials, magnetic responsive materials and conductive materials.

In one embodiment, active material-forming nanoparticles are nanoparticles for forming a semiconductor material.

The active materials form active layers, or active films. The term active layer refers to a layer in an electronic device that has electrical or optical function. Active layers include semiconductor layers (including p-type semiconductor layers and n-type semiconductor layers), light absorbing layers, charge blocking layers, charge transport layers, light emitting layers, temperature responsive layers, conductive layers, magnetic responsive layers and conductive layers. The term active film is used in a similar sense.

In one embodiment, the nanoparticles comprise at least one element selected from the group consisting of group IB, IIB, IIIA, IVA, VA and VIA elements. The elements may be in elemental (i.e. metal) form, or in composite or compound form with other elements.

The inorganic material (of which the nanoparticles are formed) may be selected from the group consisting of oxides, tellurides, selenides, sulphides and arsenides of group IB, IIB, IIIA or IVA metals.

In general, the nanoparticles may be of any inorganic material having application in solar cells.

As non-limiting examples, the nanoparticles may comprise inorganic materials selected from the group consisting of silicon, amorphous silicon, copper, copper selenide (CuSe), copper sulphide (CuS), copper telluride (CuTe), copper indium sulphide (CuInS), copper indium selenide (CuInSe), copper indium telluride (CuInTe), copper iron sulphide (CuFeS), copper indium gallium selenide (CIGS), copper zinc tin sulphide (CuZnSnS), zinc oxide (ZnO), zinc sulphide (ZnS), zinc selenide (ZnSe), zinc telluride (ZnTe), zinc indium oxide (ZnInO), zinc gallium oxide (ZnGaO), zinc aluminium oxide (ZnAlO), zinc indium selenide (ZnSnSe), zinc gallium selenide (ZnGaSe), zinc aluminium selenide (ZnAlSe), zinc tin oxide (ZnSnO), zinc tin sulphide (ZnSnS), zinc tin selenide (ZnSnSe), zinc tin telluride (ZnSnTe), zinc tin gallium oxide (ZnSnGaO), zinc tin gallium sulphide (ZnSnGaS), zinc tin gallium selenide (ZnSnGaSe), zinc tin gallium telluride (ZnSnGaTe), tin oxide (SnO), tin sulphide (SnS), indium oxide (InO), indium tin oxide (ITO), indium phosphide (InP), indium sulphide (InS), indium selenide (InSe), indium oxide (MO), indium arsenide (InAs), cadmium selenide (CdSe), cadmium telluride (CdTe), cadmium sulphide (CdS), cadmium-tellurium selenide (CdTeSe), cadmium oxide (CdO), lead selenide (PbSe), lead sulphide (PbS), gallium oxide (GaO), gallium arsenide (GaAs), gallium indium arsenide (GalnAs), gallium phosphide (GaP), iron sulphide (FeS), aluminium oxide (AlO), molybdenum trioxide (MoO₃), molybdenum dioxide (MoO₂), molybdenum trisulphide (MoS₃), molybdenum disulphide (MoS₂), molybdenum triselenide (MoSe₃), molybdenum diselenide (MoSe₂), nickel oxide (NiO), germanium (Ge) and mixtures, alloys or composites thereof.

The compounds names in parenthesis in the above paragraph are abbreviations only and should not be taken as chemical formulae. It will be understood that the inorganic materials listed in the above paragraph include materials with stoichiometric compositions and non-stoichiometric compositions. As one example, a reference to copper sulphide includes CuS and CuₓS₁₋ₓ, such as Cu_{0.9}S_{0.1} and Cu_{0.1}S_{0.9}. As another example, a reference to cadmium telluride selenide includes CdTeSe, CdTeₓSe₁₋ₓ and CdSeₓTe₁₋ₓ such as CdTe_{0.9}Se_{0.1} and CdSe_{0.9}Te_{0.1}.

The nanoparticles may be nanoparticles of the inorganic materials listed above. For example, the nanoparticles may be silicon nanoparticles, amorphous silicon nanoparticles, copper nanoparticles, copper selenide nanoparticles, copper sulphide nanoparticles, copper telluride nanoparticles, copper indium sulphide nanoparticles, copper indium selenide nanoparticles, copper indium telluride nanoparticles, copper iron sulphide nanoparticles, copper indium gallium selenide nanoparticles, copper zinc tin sulphide nanoparticles, zinc oxide nanoparticles, zinc sulphide nanoparticles, zinc selenide nanoparticles, zinc telluride nanoparticles, zinc indium oxide nanoparticles, zinc gallium oxide nanoparticles, zinc aluminium oxide nanoparticles, zinc indium selenide nanoparticles, zinc gallium selenide nanoparticles, zinc aluminium selenide nanoparticles, zinc tin oxide nanoparticles, zinc tin sulphide nanoparticles, zinc tin selenide nanoparticles, zinc tin telluride nanoparticles, zinc tin gallium oxide nanoparticles, zinc tin gallium sulphide nanoparticles, zinc tin gallium selenide nanoparticles, zinc tin gallium telluride nanoparticles, tin oxide nanoparticles, tin sulphide nanoparticles, indium oxide nanoparticles, indium tin oxide nanoparticles, indium phosphide nanoparticles, indium sulphide nanoparticles, indium selenide nanoparticles, indium oxide nanoparticles, indium arsenide nanoparticles, cadmium selenide nanoparticles, cadmium telluride nanoparticles, cadmium sulphide nanoparticles, cadmium-tellurium selenide nanoparticles, cadmium oxide nanoparticles, lead selenide nanoparticles, lead sulphide nanoparticles, gallium oxide nanoparticles, gallium arsenide nanoparticles, gallium indium arsenide nanoparticles, gallium phosphide nanoparticles, iron sulphide nanoparticles, aluminium oxide nanoparticles, molybdenum trioxide nanoparticles, molybdenum dioxide nanoparticles, molybdenum trisulphide nanoparticles, molybdenum disulphide nanoparticles, molybdenum triselenide nanoparticles, molybdenum diselenide nanoparticles, nickel oxide nanoparticles, or germanium nanoparticles.

The nanoparticles may be alloys, core-shell particles or non-spherical nanoparticles of the inorganic materials listed above or of mixtures of the inorganic materials listed above. In some embodiments, the nanoparticles may be referred to as nanocrystal alloys.

As another example, the nanoparticles may be nanoparticles of cadmium telluride and cadmium selenide composites or alloys. For example, the nanoparticles may be CdSeₓTe₁₋ₓ or CdSe₁₋ₓTeₓ such as CdSe_{0.1}Te_{0.9}, CdSe_{0.5}Te_{0.5} or CdSe_{0.9}Te_{0.1}.

According to some embodiments, the nanoparticles are cadmium telluride nanoparticles.

Nanoparticle dispersion

The term “nanoparticle dispersion” may be referred to as an “ink”. This terminology is sometimes used because the deposition method (described in detail below) corresponds to ink application or printing processes. The terms may be used interchangeably.

The nanoparticle dispersion may comprise a single inorganic material.

The nanoparticle dispersion may comprise 2 or more different inorganic materials which upon thermal annealing form an active layer of a single composition. For example, in one embodiment, the ink may contain Cu particles and In₂S₃ particles which upon thermal annealing form an active layer of CuInS₂. In another embodiment, the ink may contain Cu particles, In₂S₃ particles and Ga₂S₃ particles which upon thermal annealing form an active layer of CuIn₍ₓ₎Ga₍₁₋ₓ₎S₂.

The nanoparticle dispersion may comprise particles of inorganic materials and one or more other components such as a polymer or small molecule. The term small molecule refers to organic compounds having a molecular weight less than about 1000 g/mol, or less than about 750 g/mol, or less than about 500 g/mol, or less than about 400 g/mol and includes salts, esters and other acceptable forms of such compounds. On application of the method of the invention, crystallisation may selectively occur from the particles of inorganic material and the other component(s) may act as a matrix between the nanoparticles. In this way, films of blends of materials may be prepared by the method of the invention.

The nanoparticle dispersions may contain nanoparticles of inorganic materials of different shapes. Different shapes may be used effectively to alter the packing, porosity, strength or optical properties of the film. For example, carbon nanotubes may alter the mechanical properties and electrical conductivity of an ink based film. Examples of different particle shapes and the effect they have on devices are set out in further detail below.

The nanoparticle dispersion comprises nanoparticles dispersed in a solvent. The solvent may be any suitable liquid. In this context, the solvent is not necessarily a solvent for the nanoparticles. Another term for a “solvent” is a “liquid”.

The nanoparticles may be dispersed in a polar solvent or a non-polar solvent.

The solvent may, for example, be selected from the group consisting of toluene, chloroform, chlorobenzene, hexane, xylene, pyridine, propanol, ethanol, methanol, methylethyl ketone, dimethylsulfoxide, dimethylformamide, methoxyethanol, dichlorobenzene, trichlorobenzene, pentane, heptane, nonane, decane, dodecane, tetradecane, hexadecane, cyclopentane, cyclohexane, benzene, 1,4-dioxane, diethylether, dichloromethane, tetrahydrofuran, ethyl acetate, acetone, acetonitrile, formic acid, methyl isobutyl ketone, butanol, pentanol, hexanol, heptanol, octanol, water and mixtures thereof.

In one embodiment, the nanoparticle dispersion may contain one or more additives. The additives may be selected from the group consisting of salts, fillers, ligands, dopants and mixtures thereof.

Salt additives catalyse the growth of crystals across the layer boundaries. In one embodiment, the salt additive may be CdCl₂ or ZnCl₂ salts. CdCl₂ salts are preferably used for CdTe, CdSe, and CdS nanoparticles.

Filler additives fill the gaps between the nanoparticles and can act to control composition, doping, and/or act as crystallizing agents. In one embodiment, CdSe nanoparticles in small quantities are doped into a layer that contains CdTe nanoparticles. Thus, the nanoparticle dispersion may comprise CdTe and CdSe. The CdSe may be present in a dopant amount.

Additives which are ligands can form covalent bonds with and between nanoparticles. Ligand additives therefore allow control of surface chemistry. Ligand additives may be mono-functional ligands such as alkyl, aromatic, halogenated amines, thiols, carboxylates and so forth. Ligand additives may also be bifunctional ligands that can bridge between particles such as dithiols, diamines, dicarboxylates, and so forth.

For devices which employ a grain growth approach, for example, thin-film solar cells, it is desirable to possess short chained surface chemistry. The grain growth process is correlated to when surface ligands begin to effectively boil off the surface. Therefore, by using short chained or unsubstituted aromatic ligands which function as stabilizers, minimum shrinkage associated with loss of ligand will be experienced. This is important for reducing pinholes and cracks in the thermal annealing step(s). Furthermore, such stabilizers possess lower boiling points then more bulky or substituted counterparts. This provides the advantage of permitting grain growth to begin at lower temperatures. The term “short chained” refers to chain lengths of not more than 8 carbon atoms, preferably not more than 6 carbon atoms.

Additives which are dopants can be chemically incorporated into the crystals such that they alter the energy levels of the layer. Dopant additives may be elements of the same valence state to that existing within the nanoparticles, such as O, S, Se, Zn or Hg within CdTe nanoparticles. Dopant additives may also be elements of a different valence state to that existing within the nanoparticles such that electronic doping is achieved, for example, In, Ga, or Al, or P, As, N, CI, Br, or Ito achieve p- or n-type doping, respectively.

The amounts of additives in the nanoparticle dispersion are preferably less than 10% by weight of the solids in the dispersion (excluding solvent), more preferably less than 1% by weight of the solids in the dispersion (excluding solvent), even more preferably less than 0.1% by weight of the solids in the dispersion (excluding solvent).

### Contacting

The layers of nanoparticles are deposited on the substrate by contacting the substrate with a nanoparticle dispersion. This process may be described as solution deposition or solution processing. Any technique for contacting the substrate with a nanoparticle dispersion can be used. In one embodiment, the deposition is solution processing performed by spin-coating, dip-coating, printing, ink-jet printing, gravure printing, spray-coating, doctor blading or slot-die coating.

The nanoparticle layers may be deposited in a thickness of at least about 25 nanometres, such as at least about 50 nanometres, or at least about 100 nanometres. The nanoparticle layers may be deposited in a thickness of up to about 1 micron, such as up to about 800 nanometres. or up to about 600 nanometres, or up to about 400 nanometres, or up to about 200 nanometres, or up to about 150 nanometres.

The inorganic film may have a thickness of between about 90 nanometres and about 3 microns. Thus, the minimum film thickness may be about 100 nanometres, about 200 nanometres, about 300 nanometres, about 400 nanometres, or about 500 nanometres. The maximum film thickness may be about 2.5 microns, about 2 microns, about 1.5 microns, about 1 micron, or about 800 nanometres. Each of the lower and upper limits can be combined with each other without limitation.

The inorganic film may have a thickness of at least about 200 nanometres.

The nature of the nanoparticles (e.g. chemical composition, size, shape), the additives and/or the chemical treatment may be different for each deposited layer. A graded change in these parameters gives an inorganic film with a compositional gradient across the inorganic film and the interface with the next film or electrode may be optimised by varying the final layer or treatment process.

### Treatment

The present method utilizes a layer-by-layer method in which deposition and treatment steps are repeated multiple times.

The treatment step induces a change in surface chemistry or allows for partial sintering. Both of these processes prevent removal of the nanoparticles in subsequent layer depositing steps and in this way, multi-layers can be deposited one on top of another without removal of the nanoparticles of already deposited layers. This permits the cracks and pinholes that are formed during the chemical treatment and/or thermal annealing steps to be gradually over-coated.

The treatment step prevents the removal of the nanoparticles of already deposited layers. The prevention of removal in this context refers to preventing substantial removal of the nanoparticles. The treatment step also prevents the nanoparticles from being dissolved.

The treatment step also avoids the need for ‘orthogonal’ solvents when printing/constructing multilayer devices.

### Chemical Treatment

In one embodiment, at least one of the treatment steps (b) comprises a chemical treatment. As one example, if the method involves depositing three layers of nanoparticles, one or both of the intervening treatment steps following the deposition of the first and second layers may comprise chemical treatment and there may also be a chemical treatment step following deposition of the third (final) layer.

The chemical treatment allows the surface chemistry of the nanoparticles to be modified. The chemical treatment step may therefore comprise a surface chemistry modification step. This modification can cause controlled electrical doping and/or enhanced nanocrystallite growth during the thermal annealing step. The chemical treatment also assists to prevent removal nanoparticles of already deposited layers since the surface chemistry modification creates interactions between the nanoparticles.

The chemical treatment may be any chemical treatment known in the art of solution processing. The chemical treatment may involve contacting the layer of nanoparticles with a solution comprising one or more chemical treatment agents. The different types of chemical treatment agents may be selected from the group consisting of salts, fillers, ligands, dopants and mixtures thereof. Suitable salts, fillers, ligands and dopants are the same as outlined above for additives to the nanoparticle dispersion.

In one embodiment, the layer of nanoparticles is contacted with a solution comprising one or more chemical treatment agents selected from salts, fillers, ligands, dopants and mixtures thereof. This chemical treatment step may be applied irrespective of whether or not the nanoparticle dispersion contains additives.

The chemical treatment may be carried out in the presence of gases such as oxygen, hydrogen, nitrogen, argon, fluoroform and so forth. Carrying out the chemical treatment in the presence of gases may further aid in crystallization and/or doping of the nanoparticle layers.

According to some embodiments, the chemical treatment comprises contacting the layer of nanoparticles with a surface modifier. In some embodiments, the surface modifier comprises CdCl₂ salts, ZnCl₂ salts or CdBr₂ salts. According to other embodiments, the chemical treatment comprises contacting the layer of nanoparticles with a solution comprising CdCl₂ salts or ZnCl₂ salts.

Any suitable means can be used to contact the layer of nanoparticles with a solution comprising one or more chemical treatment agents. Suitable means are as described above for contacting the substrate with a nanoparticle dispersion and includes spin-coating, dip-coating, printing, ink-jet printing, gravure printing or slot-die coating.

### Thermal Annealing

The method involves at least one thermal annealing step in which the layer or layers of nanoparticles are thermally annealed. The thermal annealing step is suitably preformed at step (e) and it may also be performed at one or more of the treatment steps (b).

The term “thermal annealing” may be referred to as “sintering”. The term “thermal annealing” may also be referred to as “heat treating” or as a “heat treatment” step.

In the thermal annealing step, the layer is exposed to an elevated temperature under ambient (air) or an inert gas environment. The thermal annealing promotes crystal growth, sintering between nanoparticles and reduces the number of grain boundaries. This, in turn, causes the optical and/or electronic properties of the film to change and leads to better conductivity within the film.

The chemical treatments and thermal annealing may be selected such that controlled doping of the resulting films is achieved.

Treatment step (b) may comprise both chemical treatment and thermal annealing.

Layers can be subjected to a thermal annealing process either before or after any chemical treatment steps are performed. The use of nanoparticles greatly reduces the temperature needed for thermal annealing. The thermal annealing therefore occurs under milder conditions than those necessary for bulk materials.

The method may include a chemical treatment step before or after the thermal annealing step (e). Thus in one embodiment step (e) may comprise chemical treatment and thermal annealing.

The thermal annealing may be carried out by any suitable thermal annealing method known in the art. In one embodiment, the thermal annealing is carried out using a radioactive heat source, a laser or a pulsed flash of light.

The temperature for the thermal annealing may be performed at an elevated temperature, and up to about 450° C. In some embodiments the temperature is up to about 430° C., or up to about 410° C., or up to about 390° C. The thermal annealing is in some embodiments performed at a temperature of at least about 250° C., such as at least about 270° C., at least about 290° C., or at least about 310° C. In some embodiments, the thermally annealing is performed at a temperature in the range of from about 250° C. to about 450° C. The temperature range may be within the range of from about 300° C. to about 400° C. In some embodiments, the temperature is in the range of 300° C. to 380° C. In some embodiments, the temperature is in the range of from about 320° C. to 380° C.

The thermal annealing may be carried out in the presence of gases such as oxygen, hydrogen, nitrogen, argon, fluoroform and so forth.

After thermal annealing, the nanoparticles typically have a diameter of at least about 5 nanometres, such as at least about 8 nanometres, or at least about 20 nanometres.

### Additional Features

The method may further involve producing a second inorganic film on a first inorganic film produced by steps (a) to (e).

The second inorganic film is a different active film to the first inorganic film. As one specific example, the first inorganic film may be cadmium telluride and the second inorganic film may be zinc oxide.

The second inorganic film can be produced by a method known in the art or can be produced by the method of the invention. Thus in one embodiment, the second inorganic film may be produced by:
(f) depositing a layer of nanoparticles on the first inorganic film by contacting the first inorganic film with a nanoparticle dispersion;
(g) treating the deposited layer of nanoparticles to prevent removal of the nanoparticles in subsequent layer depositing steps;
(h) depositing a further layer of nanoparticles onto the preceding nanoparticle layer on the first inorganic film;
(i) repeating treatment step (g) and deposition step (h) at least one further time; and
(j) optionally thermally annealing the multilayer film produced following steps (f) to (i).

In another embodiment, the second inorganic film may be produced by contacting the first inorganic film with a sol-gel. In yet another embodiment, the second inorganic film may be produced by sputtering.

Sputtering, or sputter deposition is a physical vapor deposition (PVD) method of depositing thin films by sputtering, that is ejecting, material from a target or source, which then deposits onto a substrate, in this case, the first inorganic film.

From the experimental work performed to date, certain layers/materials have been found to produce devices with good efficiencies. In the following, we have outlined process steps for producing high quality film layers.

In one embodiment, the method comprises depositing four layers of cadmium telluride nanoparticles on a substrate, chemically treating and thermally annealing following the deposition of each individual layer, depositing one layer of zinc oxide nanoparticles on the cadmium telluride inorganic film and thermally annealing the product following the deposition of the zinc oxide layer.

In one embodiment, there is provided a method for the production of an inorganic film on a substrate, the method comprising:
(a) depositing a layer of cadmium telluride nanoparticles on a substrate by contacting the substrate with a cadmium telluride nanoparticle dispersion;
(b1) chemically treating and thermally annealing the deposited layer of nanoparticles to prevent removal of the nanoparticles in subsequent layer depositing steps;
(c1) depositing a further layer of cadmium telluride nanoparticles onto the preceding cadmium telluride nanoparticle layer on the substrate;
(b2) chemically treating and thermally annealing the deposited layer of nanoparticles to prevent removal of the nanoparticles in subsequent layer depositing steps;
(c2) depositing a further layer of cadmium telluride nanoparticles onto the preceding cadmium telluride nanoparticle layer on the substrate;
(b3) chemically treating and thermally annealing the deposited layer of nanoparticles to prevent removal of the nanoparticles in subsequent layer depositing steps;
(c3) depositing a further layer of cadmium telluride nanoparticles onto the preceding cadmium telluride nanoparticle layer on the substrate; and
(e) chemically treating and thermally annealing the deposited layer of nanoparticles to prevent removal of the nanoparticles in subsequent layer depositing steps;
producing a zinc oxide inorganic film on the cadmium telluride inorganic film by contacting the cadmium telluride inorganic film with a zinc oxide nanoparticle dispersion; and
thermally annealing the product.

In one embodiment, there is provided an inorganic film produced by the above methods. The present invention also provides an inorganic film obtainable by the above method. In one embodiment, the inorganic film is a dielectric coating or a transparent conducting layer.

### Devices

### Electronic Devices

The inorganic film produced by the method of the invention is suitable for use in electronic devices. An electronic device generally comprises:
an anode;
a cathode; and
at least one multilayered film of an inorganic material, wherein the multilayered film of an inorganic material contains crystallisation between particles in adjacent layers of the film.

The electronic device may be of any type containing an anode, a cathode and an inorganic active layer. Examples include solar cells, light emitting diodes, transistors, photodetectors, light-emitting transistors, thermistors, capacitors and memristors.

### Anode

Any suitable anode material can be used. The anode material is suitably a transparent anode material. According to some embodiments the anode is a metal oxide anode, including doped metal oxides, such as indium tin oxide, doped tin oxide, doped zinc oxide (such as aluminium-doped zinc oxide), metals such as gold, alloys and conductive polymers and the like. The anode may be supported on a suitable support. Supports include transparent supports, such as glass or polymer plates.

### Cathode

Any suitable cathode material can be used. According to some embodiments the cathode is a metal or metal alloy. Suitable metals and alloys are well known in the art and include aluminium, lithium, and alloys of one or both.

The device may further comprise any additional features known in the art. Some electronic devices contain interfacial layers between one or both of the electrodes and such features may be incorporated in to the electronic devices of the present application. The devices may be constructed by any techniques known in the art.

### Solar Cell Devices

According to some embodiments, the electronic device is a solar cell. The simplest solar cell device structure is a Schottky-type cell. This type of configuration employs a multilayered film of an inorganic material, wherein the multilayered film of an inorganic material contains crystallisation between particles in adjacent layers of the film, sandwiched between two contacts, one being metallic, and also forming a non-ohmic contact. Charge separation and collection is aided through a gradient in the electric field close to the metal-semiconductor which arises from the formation of a depletion layer between the two layers. CdTe based Schottky cells may be fabricated between ITO (indium tin oxide) and Al electrodes. The charge separation and collection in this device may be aided by band bending within the CdTe near the CdTe/AI interface.

An alternate device structure employs a heterojunction between two electrodes. The heterojunction may be such that a p-type layer is in contact with an n-type layer. When the offset between the conduction and valence bands within the p and n materials is such that a type-II interface forms, charge separation is naturally benefited at the interface. In addition, provided that the materials are adequately conductive, these devices are also capable of forming a depletion region. In this case, the cell possesses p-n junction characteristics.

In some embodiments, the solar cell may comprise;
an anode;
a cathode; and
an active material film position between the anode and the cathode;

wherein the active material film comprises a multilayered film of an inorganic material, and the multilayered film of inorganic material contains crystallisation between particles in adjacent layers of the film.

The active material film may comprise a charge accepting film and a charge transport film, thus, the solar cell according to one embodiment comprises:
an anode;
a cathode; and
a charge accepting film and a charge transport film positioned between the anode and the cathode;

wherein at least one of the charge accepting film and charge transport film is a multilayered film of an inorganic material, wherein the multilayered film of an inorganic material contains crystallisation between particles in adjacent layers of the film.

In contrast to known solar cells, the solar cell described above is multilayered but because of the nature of its construction, it has crystallisation (or sintering) between particles in adjacent layers of the film and therefore minimizes the number of grain boundaries. The solar cell described above is also free of cracks.

The solar cells of the present invention, which have minimal grain boundaries and no cracks have been found to have power conversion efficiencies greater than achieved before. In one embodiment, there is provided a solar cell comprising:
an anode;
a cathode; and
a charge accepting film and a charge transport film positioned between the anode and the cathode;

wherein at least one of the charge accepting film and charge transport film is a multilayered film of an inorganic material, wherein the multilayered film of an inorganic material contains crystallisation between particles in adjacent layers of the film, and wherein the solar cell has a power conversion efficiency of at least 4%.

Preferably, the solar cell has a power conversion efficiency of at least about 4.5%, more preferably at least about 5%, more preferably at least about 5.5%, even more preferably at least about 6.5%, most preferably at least about 8%.

In one embodiment, the solar cell has a power conversion efficiency of between about 5% and about 25%, such as between about 5% and about 20%, or between about 7% and about 15%, or about 9.8%.

### Charge Accepting Film

According to some embodiments, the charge accepting film, or layer, comprises an n-type inorganic semiconductor material. Suitable n-type inorganic semiconductor materials are well known in the art, and include cadmium sulphide, cadmium selenide and zinc oxide.

### Charge Transport Film

According to some embodiments, the charge transport film, or layer, comprises a p-type inorganic semiconductor material. Suitable p-type inorganic semiconductor materials are well known in the art, and include cadmium telluride.

The solar cell comprises a charge accepting film and a charge transport film positioned between the anode and the cathode. In some embodiments, the charge accepting film is on one electrode and the charge transport film is on the other electrode. In some embodiments, the solar cell may comprise other active materials.

### EXAMPLES

Layer-by-Layer approach to Solar Cell Fabrication

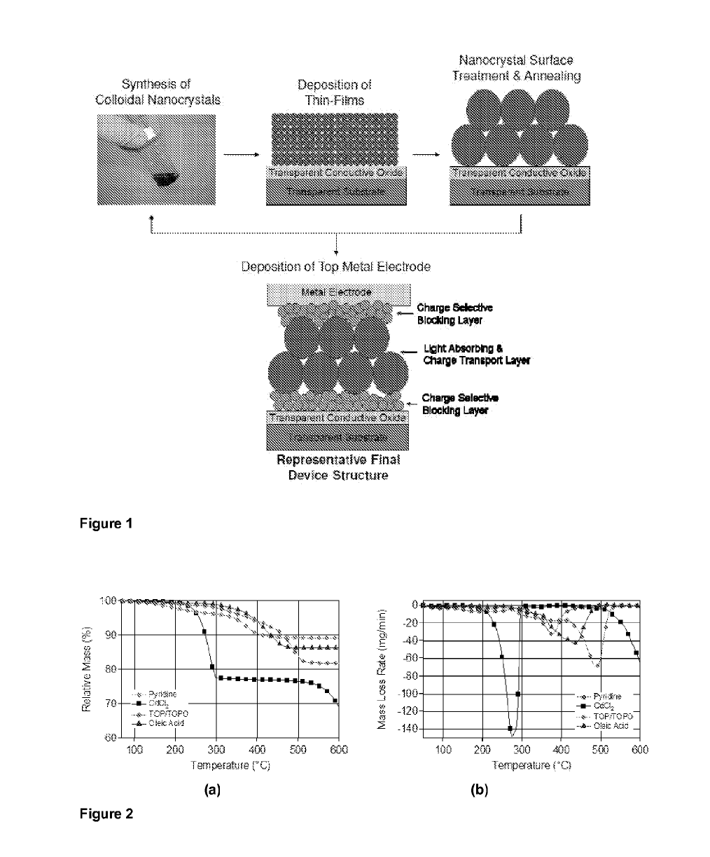

The general schematic for fabricating solution processed inorganic solar cells using a layer-by-layer technique is shown in FIG. 1. The technique begins by synthesizing a dispersion of nanoparticles of a required composition by any acceptable synthetic method which exists in the prior-art. The as synthesized nanoparticles, which are dispersed in their growth solution, are purified by filtration, centrifugation or extraction, and combinations thereof. Following purification, the surface chemistry of the nanoparticles may need to be changed to ensure dispersion in a solvent which is compatible with multi-layer deposition. The nature of the solvent may depend upon the exact treatment conditions of the deposited film, but is typically toluene, chloroform, chlorobenzene, hexane, xylene, pyridine, propanol, ethanol, methanol, methylethyl ketone, dimethylsulfoxide, dimethylforamide, or water or mixtures thereof.

Once the nanoparticles possess an appropriate surface chemistry and are dispersed in a solvent that is suitable for multi-layer deposition, a thin-film of nanoparticles is deposited onto a substrate from the dispersion by any suitable deposition method which has been described in the prior art. The thin-film is then exposed to first a chemical treatment and then, if desired, thermal annealing. The chemical treatment step is necessary to ensure that the surface chemistry of the nanoparticles is modified. This modification can cause controlled electrical doping and/or enhanced nanocrystallite growth during the thermal annealing step. In the thermal annealing step which follows, the thin-film is exposed to an elevated temperature under a vacuum, an ambient or an inert gas environment. This step promotes crystal growth and sintering between nanoparticles. Both of these effects cause the optical and electronic properties of the film to favourably change for solar cell applications.

The layer-by-layer approach can be easily integrated into solar cells by fabricating a multilayered structure of a single material on-top of a transparent conductive oxide (TCO) and depositing a top contact of an appropriate metal to cause rectification. This type of architecture is typically referred to as a Schottky device. Alternatively, one can deposit a multilayered structure, also on a TCO, with one material and then deposit another multilayered structure of a second material, or one with an opposing doping nature (e.g. p or n) on top. In this type of device configuration, the materials will form either a p-n junction or exist as a type-II interface. It may also be favourable to include charge selective blocking layers, which can be deposited on either side of the absorbing layer via the same approach, to ensure asymmetric charge flow under light. The device is completed with a top metal contact. This device architecture is known as the superstrate configuration.

Solar cells can also be made in a substrate configuration. In a substrate solar cell, the semiconducting layers are not deposited onto the TCO. Instead, they are deposited onto a suitable surface such as a metal, which acts as the back contact. Following semiconductor deposition, the TCO is then deposited as the top contact of the device. Analogous to the superstrate configuration, the substrate configuration can be used to make solar cells which behave as Schottky, p-n junctions and type-II excitonic cells.

As a model system for demonstrating the effectiveness of this layer-by-layer method, cadmium telluride (CdTe) was studied. This material was selected because it is simple to synthesize, it has a bulk optical bandgap of 1.45 eV and it possesses a high extinction coefficient. The latter two factors are desirable material characteristics for developing thin-film photovoltaics. Used within highly optimized solar cell configurations, record laboratory power conversion efficiencies (PCE) of up to 16.5% have to date been achieved with CdTe.

### Nanooarticle Synthesis

The preparation and purification protocols of all nanoparticles utilized are included in this section. Concentrations of nanocrystals (mg/mL) within the dispersions were determined by taking a known volume from a stock solution and gently removing the solvent from the aliquot by heating on a hot-plate.

### Cadmium Telluride Synthesis

In a typical CdTe synthesis 0.48 g CdO, 4.24 g oleic acid and 60 g octadecene (ODE) were heated under vacuum to 80° C. at which point the flask was purged with nitrogen. The solution was heated to 260° C. and maintained at this temperature until it turned clear. At this point a solution of 240 mg Te dissolved in 5.3 mL trioctylphosphine and 5 g ODE was rapidly injected. The resulting CdTe nanocrystal solution was allowed to cool to room temperature.

### Cadmium Selenide Synthesis

CdSe nanoparticles were prepared by an adapted method first described by van Embden et al. (Langmuir, 2005, 21, 10226-10233).

To synthesize CdSe nanocrystals with a first absorption peak at 585 nm, the following procedure was used: CdO (0.12 g, 0.938 mmol), oleic acid (1.624 g, 5.750 mmol) and ODE (24 g) were heated to 80° C. under vacuum and degassed for 30 min. The solution was heated to 310° C. under nitrogen until colourless. A solution of 1.65 g TOPSe (0.5M), bis-(2,2,4-trimethylpentyl) phosphinic acid (1.7 g, 5.86 mmol) and ODE (6 g) was swiftly injected. The growth temperature was set to 240° C. and growth of the subsequent nascent crystallites continued for ˜30 min.

### Cadmium Sulphide Synthesis

CdS nanoparticles were prepared in analogous manner to that previously described in the art by Yu et al. (Angew. Chem. Int. Ed. 2002, 41, 2368-2371).

The method involved heating 25.6 mg of CdO, 225 mg of Oleic Acid and 7.8 g of ODE under nitrogen to 300° C. The solution was cooled to 280° C. and 2 g of 0.1M elemental sulfur in ODE solution was injected. Growth of the CdS nanocrystals was conducted at 240° C.

The as-prepared CdTe, CdSe and CdS nanocrystals were washed by twice precipitating with ethanol and redispersing in toluene.

### Zinc Oxide Synthesis

ZnO nanocrystals were synthesized in similar manner to that reported in the art by Spanhel et al. (J. Am. Chem. Soc. 1991, 113, 2826-2833).

In a typical synthesis of ZnO nanocrystals, 0.44 g Zn acetate dihydrate was dissolved in 40 mL ethanol or methanol at 60° C. After 30 min of heating, 2 mL of tetramethylammonium hydroxide in 10 mL ethanol was added drop-wise to the solution over 5 min. The ZnO nanoparticle solution was heated at 60° C. for a desirable time to attain an intended ZnO nanoparticle size. For multi-layer deposition, ZnO nanocrystals dispersed in their growth solution were precipitating with hexane and centrifuged. The supernatant was discarded and the precipitated nanoparticles were redispersed in 1-propanol at an appropriate concentration.

ZnO nanocrystals using potassium hydroxide (KOH) as the base were synthesized by a protocol previously reported by Pacholski et al. (Angew. Chem. Int. Ed. 2002, 41, 7, 1188-1191). In the synthesis, 0.979 g zinc acetate dihydrate was dissolved in 42 mL methanol at 60° C. After 30 minutes heating 22 mL of a 0.4M solution of KOH in methanol was added dropwise over 10 minutes. The solution was stirred at 60° C. for a further 2 hours. The resulting solution was then centrifuged and the supernatant discarded. The precipitated ZnO NCs were re-dispersed in chloroform at the desired concentration.

The precursor solution for ZnO sol-gel films was prepared according to a modified method reported originally by Ohyama et al. (J. Ceram. Soc. Jpn. 1996, 104, 4, 296-300). In a typical preparation, 1 g of zinc acetate dihydrate was dissolved in 0.28 g ethanolamine and 10 mL 2-methoxyethanol. This solution was stirred in air at room temperature for 12 hours. This solution was passed through a 0.20 μm filter prior to deposition.

### Grain Growth of CdTe Nanocrystallites in Thin-Films

The as synthesized CdTe nanoparticles were passivated with a combination of oleic acid and tri-n-octylphosphine. Although these bulky ligands provide good colloidal stability they are undesirable for electronic purposes because they hinder electronic coupling between particles. Within electronic devices which exploit quantum confinement effects, grain growth is undesired. To induce stronger electronic coupling between nanoparticles, the ligands are typically replaced with bi-functional ligands such as hydrazine, 1,2-ethanedithiol or 1,2-diaminoethane.

For devices which employ a grain growth approach, for example, thin-film solar cells, it is desirable to possess short chained surface chemistry. The grain growth process is correlated to when surface ligands begin to effectively boil off the surface. Therefore, by using short chained or unsubstituted aromatic ligands which function as stabilizers, minimum shrinkage associated with loss of ligand will be experienced. This is important for reducing pinholes and cracks in the thermal annealing step(s). Furthermore, short chained stabilizers possess lower boiling points then their more bulky or substituted counterparts. This provides the advantage of permitting grain growth to begin at lower temperatures.

The surface chemistry of the pre-prepared nanoparticles was exchanged with compact ligands such as 5-amino-1-pentanol (AP) or pyridine. Such chemistries render the nanocrystals soluble in 1-propanol which provides appropriate surface wetting for multi-layer thin-film deposition, but are also volatile at relatively low temperatures.

For pyridine ligand exchange, the nanocrystals were precipitated with ethanol and redispersed in pyridine. This solution was placed under an inert atmosphere and stirred at 60° C. for a minimum of 12 hours. The pyridine capped nanocrystals were precipitated with hexane and re-dispersed in pyridine. Following 30 minutes of ultrasonication, the pyridine capped nanocrystals were re-precipitated with hexanes and finally dispersed in a 1:1 (v/v) solution of pyridine:1-propanol at concentrations between 10 mg/nnL to 100 mng/nnL.

Nanocrystals over-coated with 5-amino-1-pentanol were prepared by precipitating aliphatically over-coated nanocrystals from toluene by a adding an appropriate quantity of 5-amino-1-pentanol solution (10% by weight in chloroform). Following centrifugation, the supernatant was discarded and the nanocrystals were dispersed in a 1:1 solution of chloroform:ethanol at ˜20 mg/mL. To this solution an appropriate quantity of 5-amino-1-pentanol:chloroform solution was added such that the mass of nanocrystals:5-amino-1-pentanol was approximately 1:2. Surface exchange was permitted under room temperature with stirring for a minimum of 4 hours. Once sufficiently exchanged, the nanocrystals were precipitated with minimum hexane and re-dispersed in an appropriate quantity of methanol, ethanol or 1-propanol.

Thermogravimetric analysis (TGA) of nanocrystals with oleic acid, tri-n-octylphosphine/tri-n-octylphosphine oxide and pyridine surface chemistries are shown in FIG. 2. For all three surface chemistries the TGA showed two features, a relatively narrow feature at higher temperatures, and a broader feature at lower temperatures. The low temperature component of the TGA may be the residual unbound ligands thermalizing from the film. This hypothesis is substantiated by the similarity of the boiling points of the different ligands to the temperature ranges in which these contributions occur. The more prominent TGA contributions may arise from (i) adsorbed ligands being removed from the surface and (ii) loss of volatile cadmium or tellurium species. These points are also correlated to the onset temperatures for observing grain growth. Pyridine capped nanocrystals exhibit the lowest temperature onsets for both mass loss events.

Absorption measurements on the inorganic films of the invention can yield information about the size of the nanocrystals. Due to the quantum confinement effect, when the size of a semiconductor nanocrystal is smaller than its Bohr radius the bandgap will begin to shift to higher energies. Based on established size-versus absorption energy calibration curves, an estimate of the size from this measurement can be achieved. For sizes beyond the confinement regime, techniques such as XRD, AFM, and SEM are the preferred methods for determining size.

### Chemical Treatment and Thermal Annealing

Beginning with a dispersion of pyridine passivated nanocrystals, a film of ˜100 nm was deposited on a substrate to study the effects of the chemical and thermal treatment steps on the individual layers.

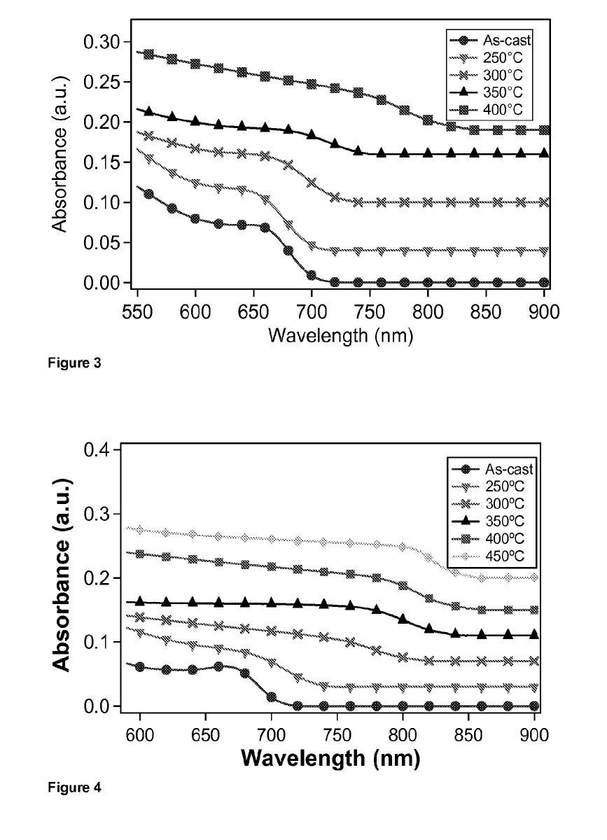

In the first instance, absorption was utilized to study the effects of thermal treatment under ambient conditions of nanocrystalline films without any chemical treatment (FIG. 3). The as-cast film showed an excitonic peak, centred near 650 nm, indicative of a quantum confined system and a size of ˜4.3 nm. Annealing at 250° C. shows some broadening of the peak and a slight redshift of the absorption onset. Annealing at 300° C. and 350° C. shows further broadening of the peak and absorption onset. The bulk absorption onset of CdTe is approximately 870 nm. It is evident that at these temperatures, there is insufficient thermal energy to induce significant crystalline growth. Once heated to a temperature of at least 400° C., this situation clearly changes as the absorption onset approaches the bulk value.

Cadmium chloride (CdCl₂) is an agent known in the art for promoting crystal growth in CdTe layers via inducing a recrystallization process at elevated temperatures (typically 400° C.). Large grain sizes are desirable for obtaining high solar cell performance, therefore exposure to a chloride environment has been found to be necessary in nearly all high-performing CdTe cells.

FIG. 4 shows the absorption spectra for CdTe films which have been soaked within a saturated solution of CdCl₂ in MeOH prior to thermal annealing. The as-cast films which had been chemically treated showed a 5 nm red-shift relative to films which were not CdCl₂ treated. This arises due to the chloride treatment partially stripping the ligands from the nanocrystal surface and also slightly increasing the particle size due to Cd deposition onto the surface. Thermal annealing of the chemically treated films at analogous temperatures to non-chemically treated samples showed a significant red-shift in the absorption. For temperatures as low as 300° C., nearly bulk absorption onset could be reached. This result demonstrates the effectiveness of the chemical treatment at promoting grain growth due to re-crystallization within a single layer.

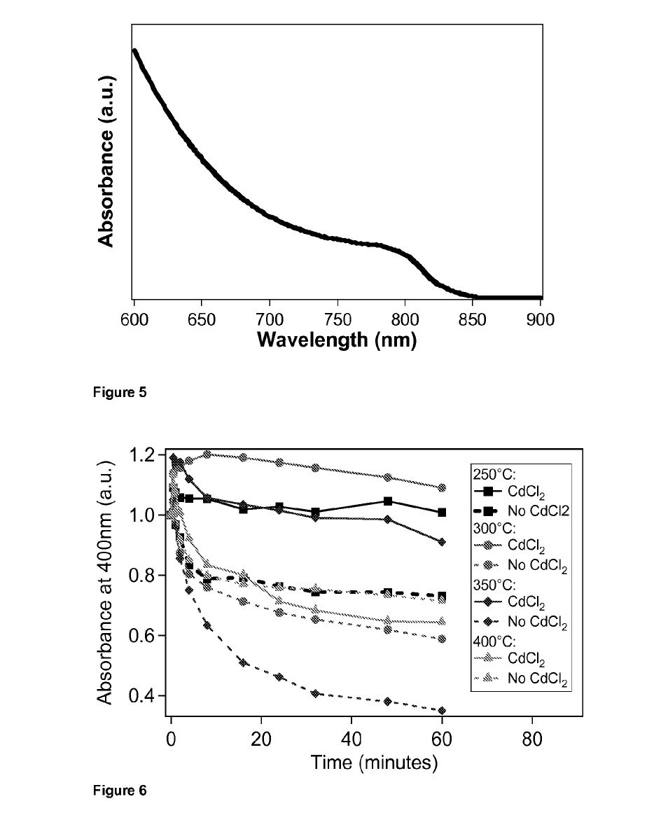

The effectiveness of the CdCl₂ treatment is not limited to soaking of the CdTe films. Large-scale grain growth can also be obtained by spin-casting a solution of CdCl₂ onto a CdTe film. As an example, a 5 mg/mL solution of CdCl₂ in MeOH was spin-cast onto a CdTe film prior to annealing at 350° C. The resulting absorption spectrum clearly demonstrates that the bulk absorption onset has been reached (FIG. 5). The grain growth is in this case facilitated due to likely surface chemistry modification during the spin-casting stage of the CdCl₂ solution. This step is therefore analogous to the soaking treatment in terms of its influence on the nanoparticle surface chemistry.

The TGA of CdCl₂ treated, originally pyridine capped, CdTe nanocrystals is shown in FIG. 2. Unlike for the pyridine capped nanocrystals, only a single major mass loss event is observed. The temperature at which the maximum mass loss occurs is approximately 280° C. This coincides exactly with the temperature range at which significant grain growth within the nanocrystalline films is observed. Notably, for pyridine capped nanocrystals, the maximum mass loss temperature is approximately 375° C. This is in good agreement with the temperature necessary for observing grain growth in pyridine capped crystallites.

In addition to crystallite size, absorption measurements can also reveal information about degradation of the films during the thermal annealing process. Accordingly, the absorbance of a film at 400nm as a function of thermal annealing time in air was measured (FIG. 6). This wavelength was chosen so as to minimize the effects of interference. The absorbance in all cases has been normalized to the value prior to any thermal annealing.

In the temperature range of 250-350° C. it can be seen that films which have not been treated with CdCl₂ show a much sharper decline in absorbance. This may be attributed to film degradation. At 400° C., film degradation is similar between the chemically treated and non-treated films and that for times longer than 16 min. The non-treated film actually shows less degradation. It can also be seen that as the annealing temperature is increased, the time at which the film begins to degrade is shortened. For example, the absorbance of a CdCl₂ treated film annealed at 300° C. reaches a maximum after 8 minutes of annealing while an analogous film annealed at 350° C. reaches a maximum absorbance value after only 30 seconds.

It is unclear by which mechanism the degradation is occurring in these films. However, annealing of CdTe in air is known to produce the wide bandgap material CdTeO₃ at the expense of CdTe, therefore this may be a possible mechanism. It is also possible that the film thickness is decreasing due to sublimation of the CdTe. Regardless of the mechanism, these results suggest that the degradation rate is directly related to crystal size. Smaller crystals have a larger proportion of surface atoms and will consequently be more susceptible to processes like oxidation. In films which have not been treated with CdCl₂, the average crystal size is relatively small below thermal annealing temperatures of 400° C. In comparison, the chemically treated films have significantly larger grain sizes. It is therefore expected that the rate of degradation in non-chemically treated films should be higher than for those that have been treated and this is observed up to 350° C. At 400° C. the non-CdCl₂ treated films approach the bulk absorption onset and the difference in crystal size compared with the CdCl₂ treated films is smaller. Degradation at this temperature is therefore similar between the two films. Overall, these results indicate that to minimize the amount of degradation in a film, it is desirable to maximize the crystal size.

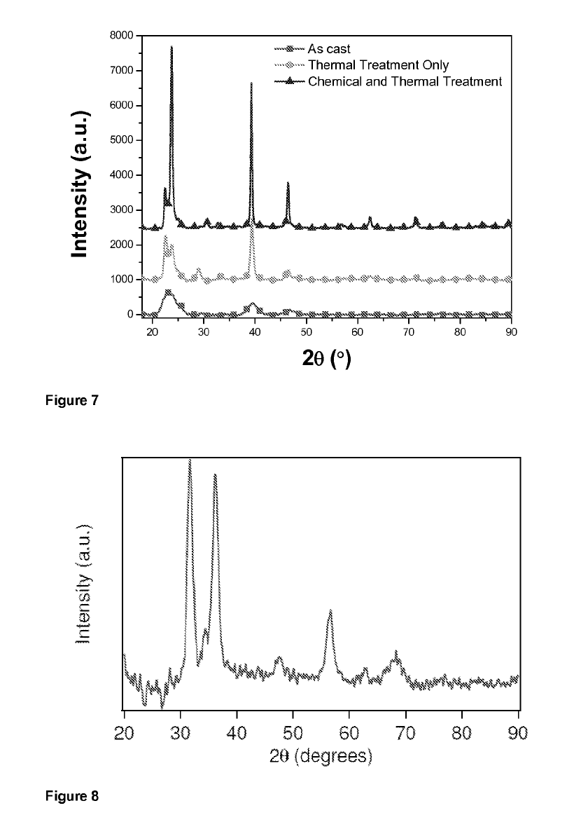

To quantify the degree of crystal growth occurring during the thermal annealing process, X-ray diffraction (XRD) and atomic force microscopy (AFM) were used. XRD is a highly useful technique to determine crystal structure, identify the co-existence of different phases, and to determine crystallite size. The results of the XRD for as deposited, chemically untreated, and chemically treated CdTe films, both thermally annealed at 350° C., are shown in FIG. 7. All films show peaks correspond predominantly to the cubic phase of CdTe. In the as-cast film, the peaks show characteristic broadening due to the small particle size of the nanocrystals. Analysis for the as-cast film yields an average crystallite size of 4 nm, consistent with that calculated from the absorption spectrum. The film which has been only thermally annealed shows that the average crystallite size has increased to approximately 19 nm. The film which has been both chemically treated and thermally annealed shows much larger growth, with an average crystallite size of approximately 67 nm. This trend is in agreement with the absorption results.

For the CdTe based solar cells, one of the device architectures employed was based on a CdTe/ZnO bilayer configuration. In this device, colloidal layers of ZnO were deposited on top of the CdTe layer, which itself was deposited by either in a single-layer or layer-by-layer chemical treatment and/or thermal annealing process. The colloidal ZnO nanoparticles utilized were approximately 5 nm in size. XRD results for ZnO nanoparticle films annealed at 300° C. are shown in FIG. 8. Peak analysis reveals that the ZnO nanoparticles only marginally increased in average crystal size to approximately 8 nm.

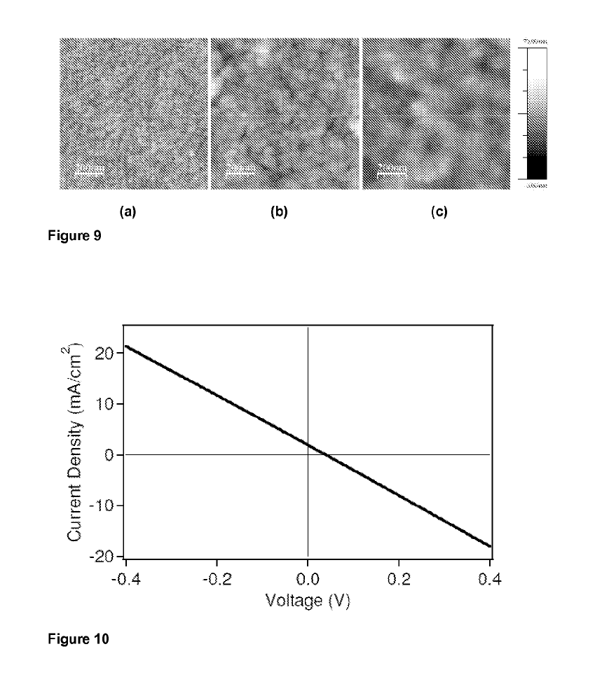

While XRD is a bulk characterization technique, AFM is specifically suited for determining the surface topography. The effects of thermal annealing on the CdTe and ZnO film surfaces are shown in FIG. 9. As-cast CdTe films exhibit nanocrystalline surface features consistent with approximately 4 nm nanoparticles and possess an rms roughness of 3.4 nm. Films which have been chemically treated and thermally annealed at 350° C. show a much larger grain size, similar to those measured from XRD. Following the depositing of four CdTe layers, via a layer-by-layer approach, with chemical treatment and thermal annealing steps between each layer, the rms roughness is 3.8 nm. This is nearly unchanged from the as-cast films and demonstrates the ability of the layer-by-layer method to create relatively smooth and uniform films. AFM measurements on the ZnO layer show a conformal, nanocrystalline coating. The rms roughness in this case remains unchanged at 3.8 nm.

### Fabrication and Characterization of Solar Cells

Reports of CdTe/CdSe bilayer devices deposited by single layer deposition and consequent chemical treatment and thermal annealing steps have shown that efficiencies as high as 2.9% could be attained. However, attempts to reproduce these results met with little success.

The devices were fabricated by first depositing a single layer of pyridine coated CdTe nanorods onto 15 Ohm/square indium tin oxide (ITO) and then heating at 150° C. to remove excess pyridine and induce some sintering. A second layer of CdSe nanorods was deposited on top of the CdTe layer and also heated at 150° C. The bi-layer structure was then chemically treated with CdCl₂ and annealed for 5min at 400° C. to induce crystal growth. As a final step, aluminium was evaporated onto the device to form the electron collecting electrode. The spatial overlap between the ITO and aluminium electrodes defined the area of each device, which was 0.2 cm². Characterization of the devices under light and dark conditions yielded typically very poor photovoltaic performance. FIG. 10 shows a typical device response under a simulated AM1.5 spectrum with an irradiance of 100 mW/cm². The nearly ohmic device performance suggests significant electrical shorting which is attributed to the formation of cracks and pinholes which span the entire thickness of the device which arise during the thermal annealing process. When the top metal electrode is evaporated, the metal clusters are able to penetrate through the defects and make contact to the ITO, which creates the short-circuit pathway.

To overcome this limitation a layer-by-layer approach is utilized in which the absorbing layer is deposited in a series of steps designed to reduce film stress and pinhole formation. For this approach spherical nanoparticles were used as they are easier to produce. However, this approach is equally applicable to nanoparticles of any shape.

Film shrinkage associated with nanorods is significantly lower than that with spherical nanoparticles. Thus, it is more difficult to achieve high quality sintered films with spherical nanoparticles.

Considering nanoparticles of spherical, cylindrical and cubic shapes, with no ligand shell, the maximum volume fraction which is occupied under a cubic close packing is independent of size and is 74%, 79% and 100%, respectively. This suggests that cubic nanoparticles would result in no film shrinkage, while cylindrical particles and spherical nanoparticles would experience a similar extent. In reality, nanoparticles must be stabilized and when the stabilization mechanism is ligand based, the size of the nanoparticles becomes critical to determining the volume fraction.

Nanoparticles used to develop the inorganic films of the invention typically possess a 2 nm radius. Cylinders with this radius and a typical length to radius ratio of 8:1, and cubes with vertices of length 8 nm (for example, double the radius of the particles), all passivated by ligands with a length of 0.5 nm (typical for smaller molecules), can be shown to have the volume fractions of 38%, 49% and 51%, respectively. Therefore the affect of the ligands is to reduce the volume fraction of spheres by nearly 30% in comparison to cylinders, while causing the occupied volume fraction of cylinders to become similar to that of cubes. This analysis, suggests that for nanoparticles of a spherical geometry, it is significantly more difficult to develop thin-films than for nanorods (approximated as simple cylinders) and nanocubes.

The surface chemistry of the nanocrystals is important for successful application of nanocrystals within a layer-by-layer approach using chemical and thermal treatment steps. In this work, numerous polar and non-polar surface ligands were tried, but 5-amino-1-pentanol (AP) and pyridine were selected. Nanocrystals capped with AP create high-quality films and yield reasonably good device performance, however the ligand exchange process was difficult to reproduce. Often the CdTe coated with the AP ligands would not fully disperse or would agglomerate within a number of hours. In order to improve the reproducibility of the process and the stability of the nanocrystals, a synthesis was developed in which the as-cast CdTe are capped only with oleic acid which was then exchanged for pyridine. The use of pyridine as the co-ordinating ligand provides several advantages over AP. The solutions of pyridine capped nanoparticles are readily re-dispersed and are stable indefinitely in solution when stored in an inert environment. Pyridine is also a small and weakly bound ligand with a relatively low boiling point which allows for better film packing and easier removal via annealing.

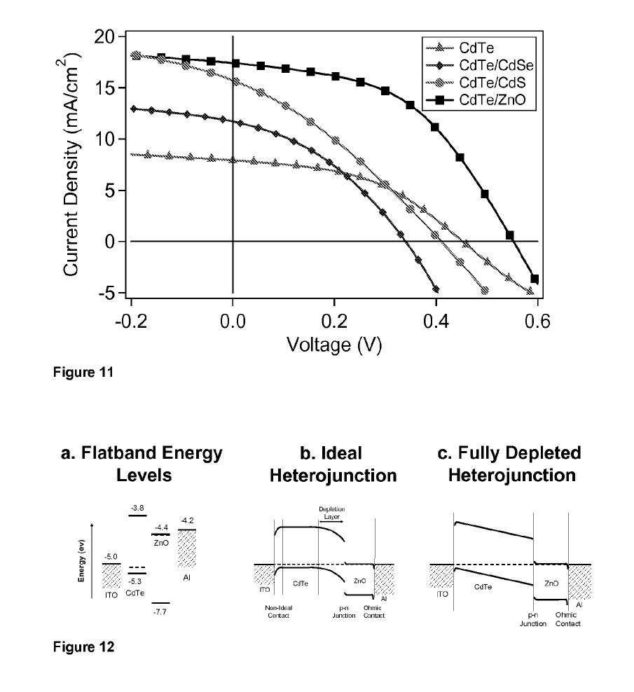

Using the layer-by-layer approach of the invention, fabrication of solar cells with a CdTe absorbing layer has been achieved. The solar cells may be heterostructured devices or Schottky devices and the results of these devices are shown in FIG. 11 and Table 1.

TABLE I
Performance characteristics for device structures

| Structure | J_{sc} (mA/cm²) | V_{oc} (V) | FF | PCE (%) |
|---|---|---|---|---|
| CdTe | 7.9 | 0.45 | 0.45 | 1.62 |
| CdTe/CdSe | 11.7 | 0.34 | 0.37 | 1.49 |
| CdTe/CdS | 15.7 | 0.41 | 0.31 | 2.01 |
| CdTe/ZnO | 17.4 | 0.56 | 0.48 | 4.65 |

The Schottky device exhibits reasonable performance with an overall efficiency under AM1.5 conditions of 1.6%. The performance with CdS and CdSe are comparable to that of the Schottky device in terms of efficiency, however a major difference is observed in their fill-factor and short circuit current densities. Utilizing ZnO as an n-type material, shows a significant improvement in all other devices in terms of all device characteristics, with an efficiency in this case of 4.65%.

A comparison of the short circuit current between all devices shows that heterostructured devices exhibit higher current densities than those based on Schottky barrier. While the fill-factor and open circuit voltage for CdTe/CdS and CdTe/CdSe devices were lower than a single layered CdTe device, the CdTe/ZnO showed a significant improvement to all aspects of device performance. This enhancement may be due to a number of reasons. Firstly, ZnO nanocrystals are synthesized with the use of acetate ligands as surface passivants. These ligands permit charge to pass easily between nanocrystals. Secondly, oxygen desorption from the surface of ZnO nanocrystals following UV light absorption, yields a highly conductive, n-type characteristics. These are desirable for electron transport and for the formation of a p-n junction that depletes mainly within the CdTe. Unlike ZnO, CdS and CdSe only become highly conductive under light absorption. The large absorption coefficient of CdTe prevents significant light intensity to be achieved within these layers. This naturally lowers the expected conductivity of both CdS and CdSe layers compared to ZnO within this device architecture. Finally, it is likely that the CdSe and CdS layers were not optimized for achieving adequate growth during the thermal annealing steps. The increased number of grain boundaries in such films would significantly hinder the electron transport through these layers and thus decrease the maximum fill-factor, short-circuit current and open circuit voltage.

It is therefore evident that heterostructured devices architectures have significantly higher potential than their single junction analogues as device architectures for developing high efficiency solar cells.

In FIG. 12, the flat band potentials for each device component within a typical ITO/CdTe/ZnO/AI heterostructured device are shown relative to vacuum. The position of the ITO work function and CdTe valence band were determined by photoelectron spectroscopy in air (PESA) measurements. The CdTe conduction band level was determined from the optical bandgap as determined by absorbance measurements. ZnO energy levels have been taken from previous works. Using a bulk semiconductor physics approach which ignores surface pinning effects, the re-alignment of the bands when the materials are brought into contact is shown (FIG. 12). Provided that materials are adequately conductive, contact between an n and p type material will form a p-n junction. This is the case even under moderate light conditions for CdTe/ZnO junctions. Under standard AM1.5 illumination conditions, photoexcitation of the CdTe/ZnO heterostructure results in absorption predominantly within the CdTe layer. Due to the high dielectric constant of CdTe, excitons within crystallites with a grain diameter larger that approximately 25 nm should dissociate at room temperature without the need of any additional driving force. For smaller crystallites, the excitons will be bound and will require a further driving force to separate the charges. This may be a type-II interface, an electric field gradient, a surface state trap, as well as any other known exciton dissociating mechanism.

For large crystallites, photogenerated electrons in the CdTe will either diffuse or be aided by the built-in field at the CdTe/ZnO interface and drift towards to the ZnO layer before being collected at the Al contact. The photogenerated holes, which will be formed within the CdTe layer in this case, will tend to experience mainly diffusion towards the ITO. Holes generated within the depletion layer will be aided by the built-in field and experience drift. In addition to the p-n junction mechanism, the type-II heterojunction formed between CdTe and ZnO will reduce recombination across this interface. When the majority carriers in the CdTe are fully depleted by the p-n junction or surface states, a near uniform spatial electric field across the CdTe layer results (FIG. 12). This situation differs from the above mentioned case in that no depletion layer exists. This ensures that the drift contribution to carrier collection is higher close to the ITO/CdTe contact, and thus potentially aids in achieving higher photocurrents, particularly when non-ideal contacts are present.

For smaller crystallites, which possess bound electron-hole pairs, exciton dissociation will occur within the vicinity of the p-n junction. The gradient field and the type-II interface in this case act to dissociate the excitons to form free charges. In the device structure, significant light absorption occurs in the CdTe near the ITO/CdTe interface. It is therefore expected that current densities in this case should be significantly lower than for large crystallite solar cells due to the limited number of excitons formed within the exciton dissociating regime. This factor is not just a limitation of the ITO/CdTe/ZnO/AI device structure, but is a significant issue with many quantum confined nanocrystallite solar cells.

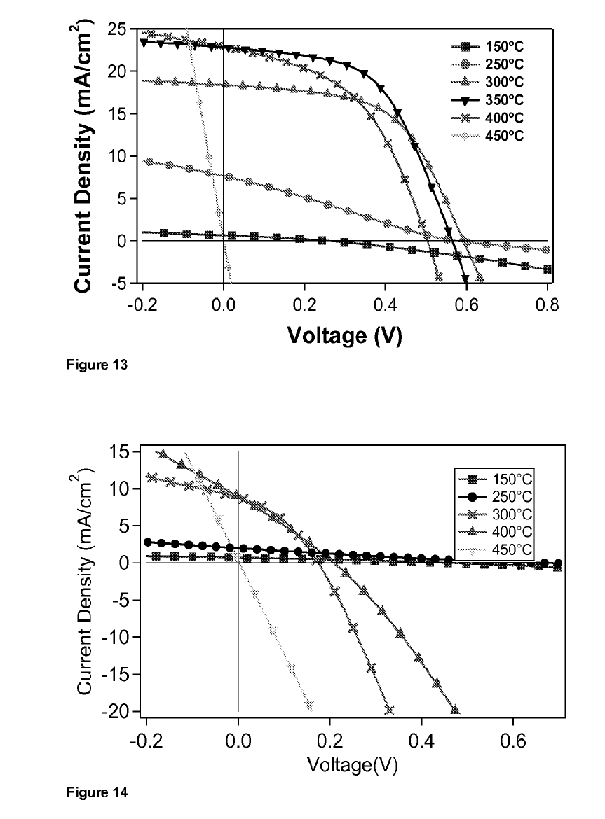

Based on the study of crystallite growth in nanocrystalline CdTe thin-films, it seems that the parameters of the thermal annealing step play a significant role in the device characteristics. To further understand this step, a study of the influence of annealing temperature on the device performance was conducted. For each deposited CdTe layer, a 1 minute thermal annealing time was applied. As shown in FIG. 13 and Table II, the variation in the annealing temperature has a significant affect on the device performance.

TABLE II
Performance characteristics for CdTe/ZnO devices with
different annealing temperature for the CdTe layers

| Annealing Temperature | J_{sc} (mA/cm²) | V_{oc} (V) | FF | PCE (%) |
|---|---|---|---|---|
| 150° C. | 0.71 | 0.45 | 0.30 | 0.10 |
| 250° C. | 9.00 | 0.64 | 0.27 | 1.54 |
| 300° C. | 18.37 | 0.59 | 0.55 | 6.07 |
| 350° C. | 22.40 | 0.57 | 0.54 | 6.88 |
| 400° C. | 22.87 | 0.51 | 0.47 | 5.47 |
| 450° C. | 0.00 | 0.00 | 0.00 | 0.00 |

Thermal annealing at temperatures of 250° C. and below resulted in poor device performance. A significant improvement in device characteristics was observed when the thermal annealing temperature was increased to between 300 and 400° C. Higher temperatures caused degradation of the films and consequently all devices exhibited electrical shorting. Analogous behaviour is observed for Schottky devices at all temperatures (see FIG. 14 and Table III).

TABLE III
Performance characteristics for CdTe-only devices annealed
at different temperatures

| Annealing Temperature | J_{sc} (mA/cm²) | V_{oc} (V) | FF | PCE (%) |
|---|---|---|---|---|
| 150° C. | 0.71 | 0.45 | 0.30 | 0.10 |
| 250° C. | 1.97 | 0.60 | 0.21 | 0.27 |
| 300° C. | 8.67 | 0.16 | 0.34 | 0.48 |
| 400° C. | 8.67 | 0.20 | 0.26 | 0.45 |
| 450° C. | 0.00 | 0.00 | 0.00 | 0.00 |

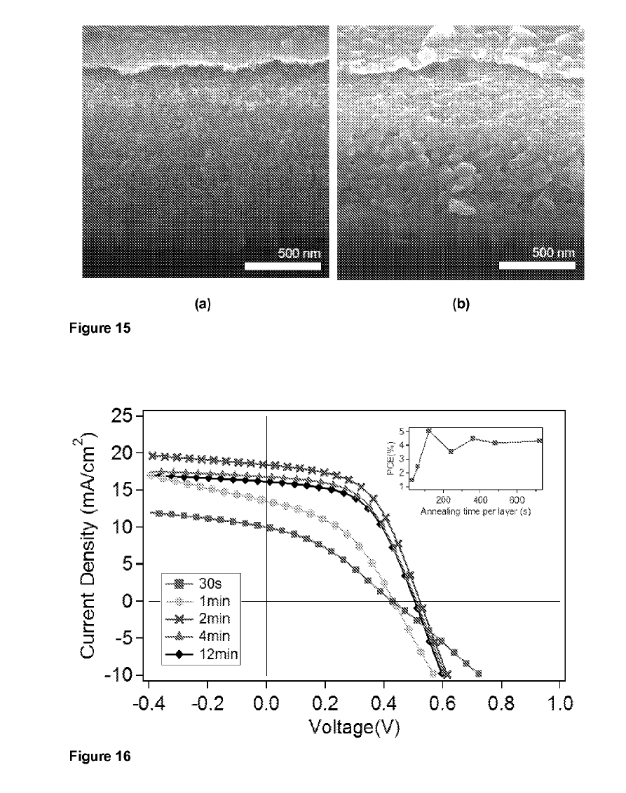

A scanning electron microscope image of the final ITO/CdTe/ZnO/Al device after annealing at 350° C. is shown in FIG. 15. For comparison, a scanning electron microscope image of a device where the CdCl₂ chemical treatment step was omitted is also shown. As can be seen in FIG. 14, the crystallite size is significantly smaller within the CdTe layer in this case where the CdCl₂ chemical treatment step was omitted. The electrical and morphological characteristics agree well with that of the absorbance measurements. At 250° C. the extent of crystal growth in the CdTe is limited. This translates to high exciton binding energies and a large number of grain boundaries in the film. Both of these factors reduce the likelihood of charge collection following light absorption in the CdTe. In addition, at these temperatures residual surface ligands are likely to remain on the surface of the crystals, further hindering charge transport. At temperatures above 300° C. recrystallization of the film occurs. This acts to reduce both the exciton binding energy and the number of grain boundaries within the film. Both of these factors significantly improve the charge collection efficiency of photogenerated electrons and holes.

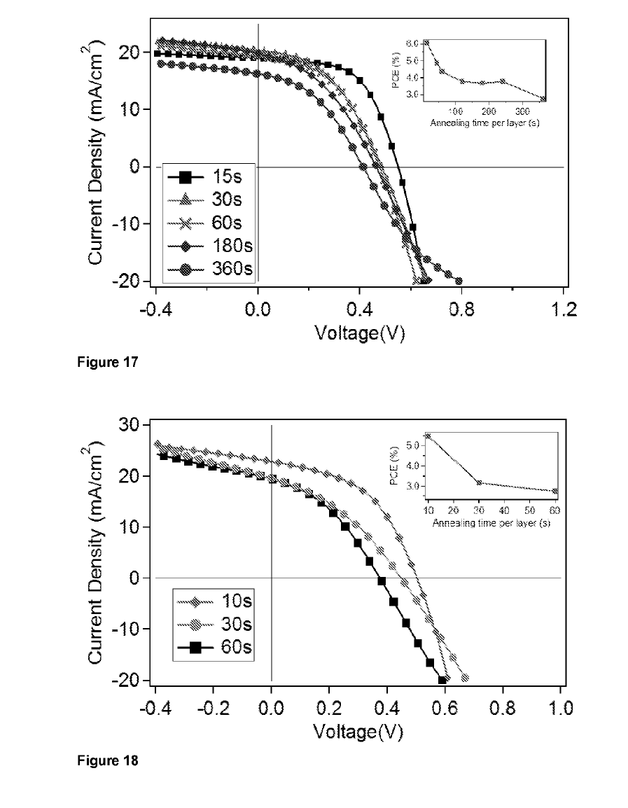

These results show that the thermal annealing temperature plays a vital role in the device performance. To further optimize the devices, the thermal annealing time of each layer at temperatures between 300 and 400° C. was varied (FIGS. 16-18). It was seen that at a thermal annealing temperature of 300° C., the optimal time for each layer to be annealed was 2 minutes, at a thermal annealing temperature of 350° C. it was only 30 seconds and at a thermal annealing temperature of 400° C. it was 10 seconds. The trends seen in these results correlate well with the degradation experiments. This suggests that at the ideal annealing times the best balance between crystal growth and degradation was achieved. It should be noted that power conversion efficiencies of >5.5% have been achieved for all three thermal annealing temperatures.

Previous reports have suggested that temperatures of 400° C. are necessary to achieve good efficiencies in sintered, nanocrystal solar cells. However, the use of the method of the invention evidently allows the use of significantly lower temperatures. This reduces the energy input needed to fabricate the cells, and allows high efficiencies to be achieved at temperatures compatible with certain flexible substrates.

Prior reports have also stated that the sintering process was performed for 15 minutes. With the method of the invention, the amount of time needed for the sintering process has been dramatically reduced. This will further decrease fabrication costs.

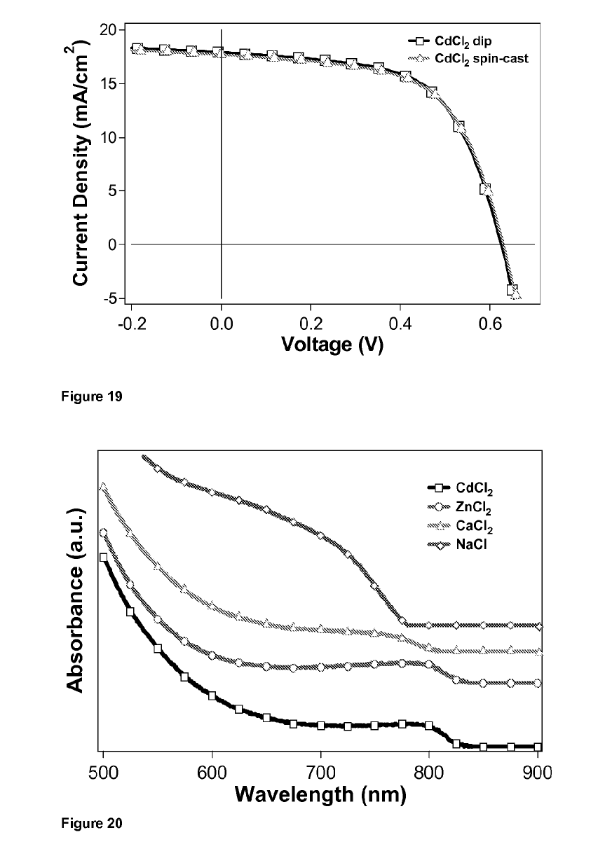

It is worth noting that the lower temperatures used in the method of the invention can yield efficient devices when the CdCl₂ treatment is performed by soaking the CdTe films in a saturated CdCl₂ solution or by depositing a layer of CdCl₂ onto the CdTe using methods such as spin-coating. Otherwise equivalent devices have been made where one was dipped in CdCl₂ solution and the other utilized a spin-cast solution of 5 mg/mL CdCl₂ in MeOH. The performance results for the devices are nearly identical (FIG. 19).

In addition to CdCl₂, several other metal chloride salts were investigated. Many of these salts, NiCl₂, MgCl₂ and CuCl₂ clearly damaged the CdTe and were not investigated further. Among the salts that did not visibly damage the CdTe were ZnCl₂, CaCl₂ and NaCl. Films of CdTe were treated with these metal chlorides and then annealed at 350° C. The absorption spectra of these films (FIG. 20) show that when ZnCl₂ is used the bulk absorption onset of CdTe is reached, indicating significant grain growth. For CaCl₂ and NaCl the bulk onset is not reached, indicating that grain growth is limited when these salts are used.

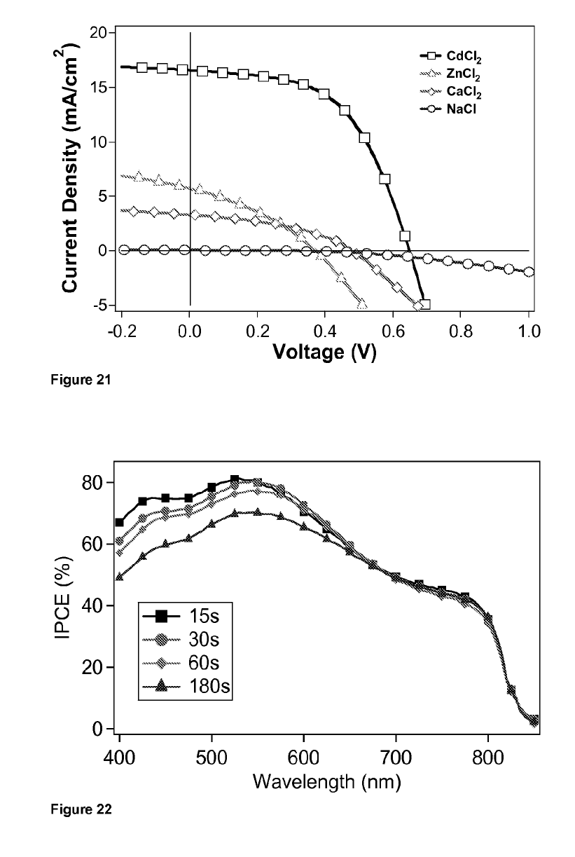

Solar cells were made using CdTe layers treated with each of ZnCl₂, CaCl₂ and NaCl, as well as a reference device treated with CdCl₂. The resulting current-voltage curves are shown in FIG. 21. As expected, the CaCl₂ and NaCl treated devices exhibit poor performance due to limited grain growth. Despite achieving larger scale grain growth the ZnCl₂ treated cell also performs relatively poorly. This may be due to changes in the electronic properties of the CdTe layers such as doping density.

Current-voltage characteristics provide information on how a device performs under 1 sun illumination. By studying the incident photon conversion efficiencies (IPCE), information on how a device performs spectrally can be determined. This can give insight into interference losses and also recombination mechanisms. In FIG. 22, the IPCE of devices which have been annealed for different times at 300° C. are shown. The results show that at longer annealing times the IPCE undergoes a steady decrease at wavelengths less than approximately 650 nm, while at longer wavelengths it remains virtually unchanged. This observation indicates that charges which have been generated as a result of light absorption at wavelength <650 nm are less likely to be collected with increasing annealing time. Notably, in all these devices, the thickness of the CdTe layer was constant at ˜400 nm.

Like all inorganic semiconductors, CdTe absorbs more strongly at higher photon energies than close to its band-edge. This translates to a greater portion of incident light being absorbed near the ITO/CdTe interface. At lower energies photons will tend to be absorbed further into the device. Therefore, the decrease in IPCE at wavelengths <650 nm may be due to increased charge recombination occurring near the ITO/CdTe interface. One possibility is that either indium or tin from the ITO diffuses into the CdTe. As both indium and tin are n-type dopants in CdTe, their presence would cause bending of the CdTe bands near the ITO interface. This would result in an unfavourable drift direction of both electrons and holes at this interface. Its effect would be to increase the overall charge recombination close to the ITO/CdTe interface within the device.

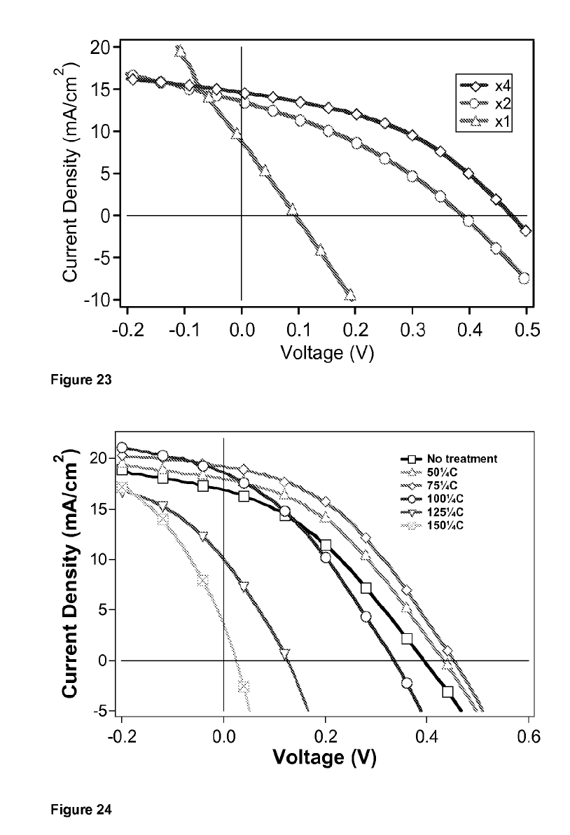

A summary of the device performance of CdTe/ZnO solar cells when the CdTe layer was thermally annealed under a number of different conditions is provided in FIG. 23 and Table IV.

TABLE IV
Performance characteristics for CdTe/ZnO devices with the CdTe
layers being thermally annealed at different points during
fabrication, under a nitrogen environment and after Al deposition

| CdTe Annealing conditions | J_{sc} (mA/cm²) | V_{oc} (V) | FF | PCE (%) |
|---|---|---|---|---|
| All 4 layers | 14.63 | 0.47 | 0.41 | 2.85 |
| Layers 2, 4 | 13.54 | 0.39 | 0.33 | 1.76 |
| Final layer | 8.86 | 0.10 | 0.24 | 0.23 |
| Every layer under N₂ | 2.67 | 0.12 | 0.27 | 0.09 |
| Every layer + after Al | 0.06 | 0.08 | 0.23 | 0.001 |
| deposition | | | | |

From these results, it is seen that film deposition conducted in a layer-by-layer fashion, but only thermally annealing following the final layer deposition, results in device failure due to electrical shorting. The same outcome is observed when the annealing is conducted after every two layers in a 4 layer device. However, thermal annealing does not need to be performed after every single layer as films with 6 and 8 layers show good performance when the annealing step has been performed only 4 times. Further experiments have shown that 3 annealing steps are sufficient to prevent shorting issues in the majority of devices.

The effect of annealing a CdTe/ZnO device following aluminium deposition has also been examined. Annealing the device was found to lead to improved performance, with a maximum being achieved at an annealing temperature of 75° C. (FIG. S5, Table V).

TABLE V
Performance characteristics for solar cells annealed at different
temperatures following Al deposition.

| Annealing | | | | PCE |
|---|---|---|---|---|
| Temperature (° C.) | J_{sc} (mA/cm²) | V_{oc} (V) | FF | (%) |
| No Treatment | 16.9 | 0.39 | 0.35 | 2.3 |
| 50° C. | 18.0 | 0.43 | 0.38 | 3.0 |
| 75° C. | 19.2 | 0.45 | 0.40 | 3.4 |
| 100° C. | 18.6 | 0.33 | 0.34 | 2.1 |
| 125° C. | 10.0 | 0.13 | 0.27 | 0.4 |
| 150° C. | 3.6 | 0.03 | 0.21 | 0.02 |

Annealing at this temperature likely improves contact between the ZnO and the Al. At higher annealing temperatures performance steadily deceases, likely due to diffusion of the Al through the device.

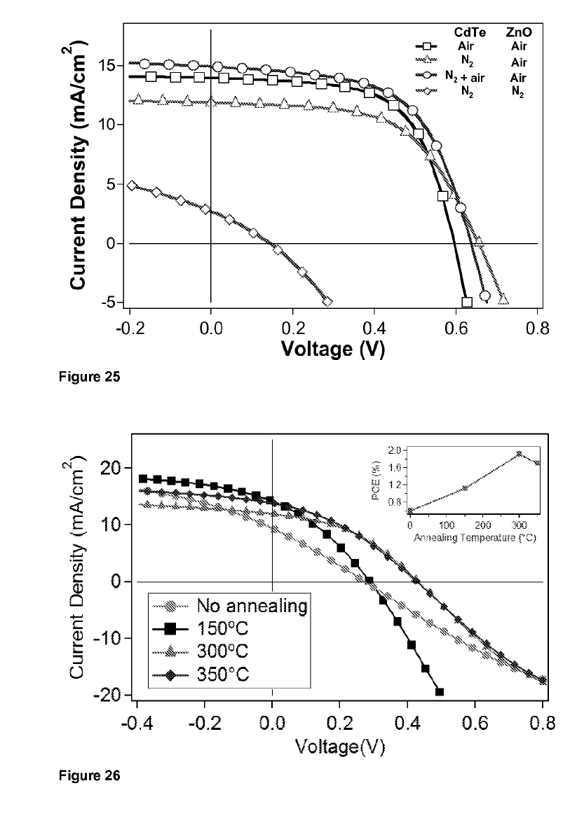

Using a typical CdTe/ZnO device, the effects of annealing within a nitrogen atmosphere were also investigated. When both the CdTe and ZnO layers are annealed exclusively in a nitrogen atmosphere device performance is poor. However, when the CdTe layers are first annealed in nitrogen and then in air following the final CdTe layer, device performance is comparable to those which have been annealed exclusively in air. The air-annealing step can also be performed following ZnO deposition (FIG. 25). This is in agreement with previous studies on bulk CdTe solar cells which have found that annealing in the presence of oxygen leads to improved device performance.

Thermal annealing conditions for the ZnO layer also affect cell performance. The results of different annealing temperatures for the ZnO layer are shown in FIG. 26. Annealing at 300° C., rather than 150° C. gives better a performance for all device characteristics. This may be due to an increase in size and improved crystallinity of the zinc oxide nanocrystals.

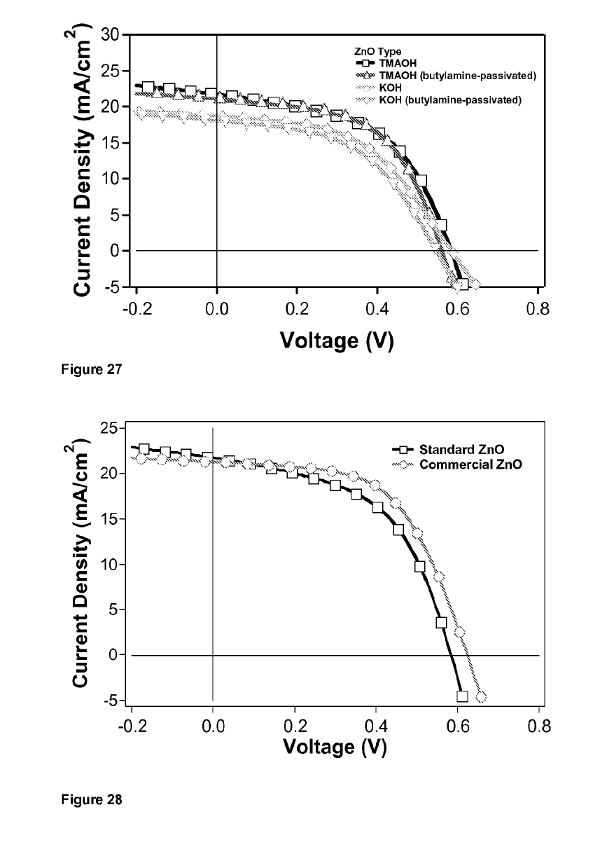

The effect of using ZnO nanocrystals prepared by different synthetic methods on device performance has also been examined. Synthesizing the nanocrystals using KOH as the base rather than TMAOH renders the nanocrystals soluble in chloroform. The addition of short-chained amines to passivate the particle surface can improve the mobility of ZnO nanocrystals while also making them soluble in chloroform. As shown in FIG. 27 solar cell performance is relatively independent of the ZnO preparation method. As ZnO nanocrystals are highly conductive following UV illumination it is likely that charge transport through the ZnO is not a limiting factor for solar cell performance.

In addition to freshly prepared colloidal ZnO nanocrystals, commercially available ZnO nanocrystals (purchased from Degussa) of approximately 30 nm dispersed in water were also used. Although the devices fabricated from these commercially available particles were visibly much rougher, the device performance was comparable when each was annealed at 300° C. (FIG. 28).

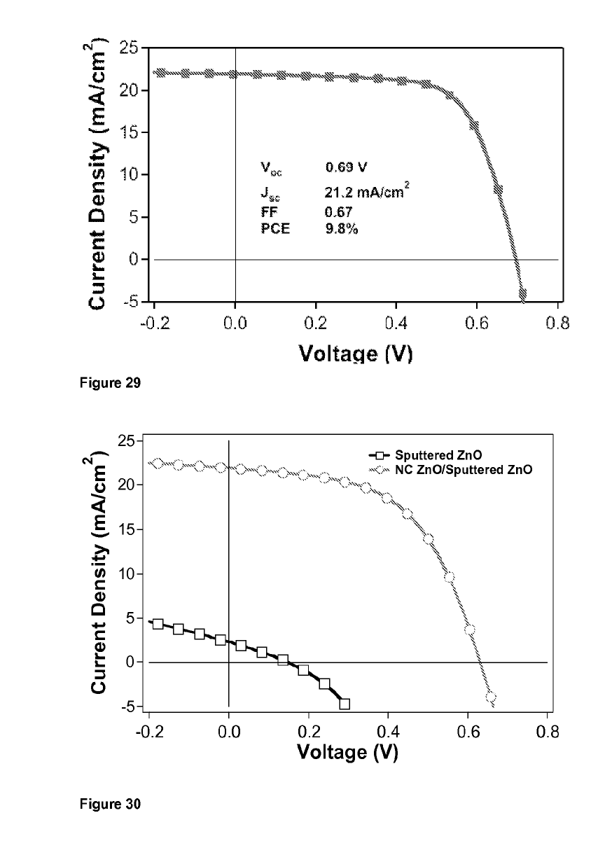

In addition to ZnO nanocrystals, the effect of using ZnO prepared by a sol-gel method has also been examined. In this approach a precursor solution was deposited on top of the CdTe layers, followed by annealing at 300° C. Using the sol-gel method power conversion efficiencies of 9.8% have been obtained (FIG. 29). This increase in performance relative to ZnO nanocrystals is largely due to a higher fill factor. It is thought that there are two explanations for this increase. One is that the sol-gel ZnO results in an amorphous layer when annealed at 300° C. This means the ZnO layer will be free of grain boundaries which may be detrimental to device performance. The second is that sol-gel ZnO provides a conformal coating of the CdTe, resulting in intimate contact between the p-type and n-type layers. This may not be the case for ZnO nanocrystals where some void space is expected.

The effect of depositing a ZnO layer using a physical vapor method, namely sputtering, has also been examined. When sputtered ZnO is deposited on top of the CdTe layers device performance is very poor (FIG. 30). This is likely because sputtered ZnO is intrinsically doped. As a result it has a much lower doping density than nanocrystalline ZnO. This decreases the width of the depletion layer within the CdTe, which will hinder charge separation and collection. When a sputtered ZnO layer is deposited on top of a nanocrystalline ZnO layer device performance is much better. In this instance the highly n-doped nanocrystal layer aids charge separation while the sputtered layer acts as an electron transport layer.

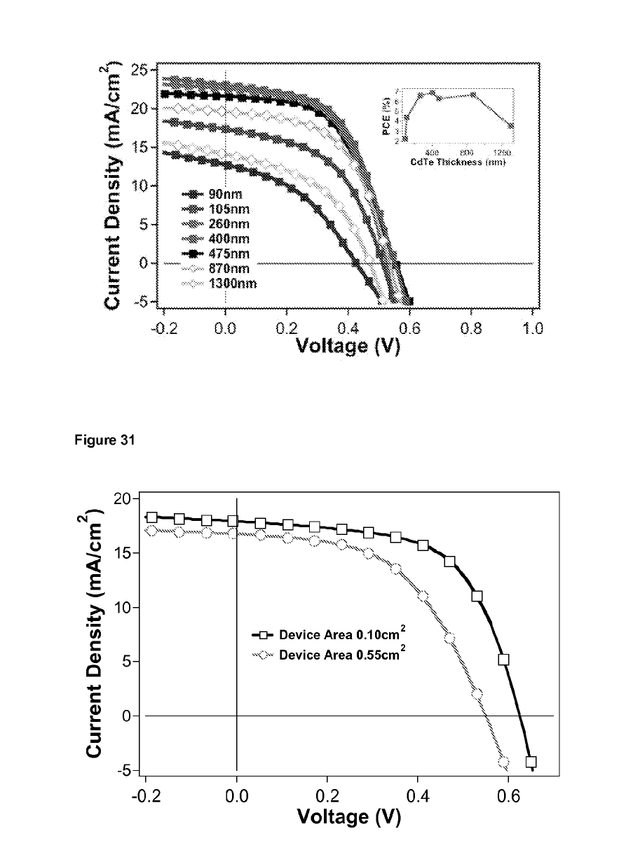

The effect of changing the CdTe thickness at an optimal thermal annealing temperature of 350° C. for 15 seconds per layer was also investigated (FIG. 31). The thickness was varied by changing either the spin speed or the number of layers deposited, but in all cases the CdTe layers were chemically treated and thermally annealed a total of 4 times. The ZnO layer thickness was a constant 60 nm for each device.

Devices with CdTe thicknesses as small as 90 nm were fabricated free of electrical shorting. At smaller CdTe thicknesses, the short-circuit current, Jsc, of the device was found to be limited by the inability of the CdTe to absorb adequate incident light. The best results were obtained for CdTe thicknesses of greater than 260 nm. Cells with high efficiency have been obtained for CdTe thicknesses of up to 870 nm. Beyond this thickness range, the Jsc started to decrease again. This may be due to an increase in the distance that minority carriers, electrons in the case of p-type CdTe, must travel in order to reach the CdTe/ZnO interface.

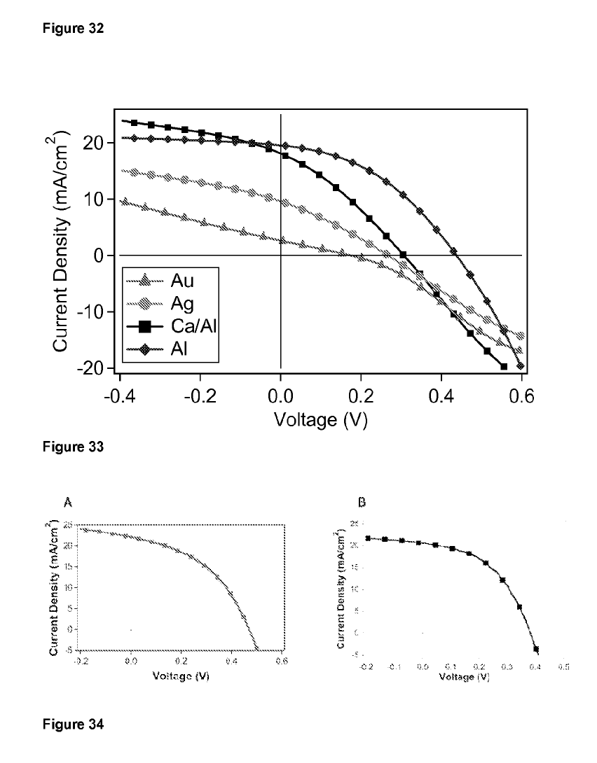

Having optimized the conditions for achieving high PCE it was sought to make devices with a larger active area. This was achieving by increasing the size of the top metal contact which overlaps with the patterned TCO substrate. With this approach cells were made with an active area of 0.55 cm2. The performance of this cell and another cell made in parallel having an active area on 0.10 cm2 are summarized in FIG. 32 and Table VI.

TABLE VI
Performance characteristics of CdTe/ZnO solar cells with
different device areas.

| | | | | PCE |
|---|---|---|---|---|
| Device Area (cm²) | J_{sc} (mA/cm²) | V_{oc} (V) | FF | (%) |
| 0.10 | 17.7 | 0.62 | 0.60 | 6.6 |
| 0.55 | 16.6 | 0.55 | 0.52 | 4.7 |

As can be seen from Table VI, with the larger area device a PCE of 4.7% was achieved, compared to 6.6% for the smaller device. Some of this decrease may be due to increased resistance in the collection of charges through the TCO layer. It may also be that larger area devices will have more shunt pathways which decrease the performance of the cell.

The influence that the top electrode has on device performance was also investigated and the results of having different metal top contacts on the devices are summarized in FIG. 33 and Table VII.

TABLE VII
Performance characteristics of CdTe/ZnO devices with
different metal top contacts

| Electrode | J_{sc} (mA/cm²) | V_{oc} (V) | FF | PCE (%) |
|---|---|---|---|---|
| Au | 2.62 | 0.17 | 0.25 | 0.12 |
| Ag | 9.59 | 0.27 | 0.29 | 0.74 |
| Ca/Al | 18.10 | 0.31 | 0.30 | 1.71 |
| Al | 19.51 | 0.44 | 0.40 | 3.44 |

There is a strong variation in device performance associated with changing the top contact. Gold and silver were the two worst performing metals. This was followed by Ca/AI and the best results were obtained with Al. The work function of the studied metals span nearly 2 eV in energy, however, the variation in Voc is less than 0.2 eV. The Au electrode showed a positive photo-voltage despite it possessing a higher work function than ITO. This suggests that either Fermi level pinning is occurring at the ZnO/metal interface or the field associated with the depletion layer is capable of overcoming the slight work function mismatch between top and bottom electrodes. A similar argument can be made for silver. Interestingly, Ca/Al showed reasonable photocurrents, but a reduced Voc compared to Al. This observation is most likely the result of the inherent electrochemical high instability of Ca when in contact with zinc salts. The interfacial reaction would undoubtedly generate Zn metal and a sacrificial insulating layer of calcium oxide.

To this point, the focus has been on devices made using pyridine capped CdTe nanocrystals dispersed in mixtures of pyridine and alcohols. It will now be shown that the method of the invention is not restricted to this particular surface chemistry or solvent mixture. In FIG. 34(a) data is shown for a solar cell made with oleic acid stabilized CdTe and deposited from chloroform. This process removes the need for a ligand exchange step between CdTe synthesis and deposition. While the cell shows a high Jsc, the Voc and FF are low compared to cells made using pyridine capped CdTe. This may be due to the fact that oleic acid is a much larger ligand than pyridine. As a result there will be more space between the CdTe nanocrystals as they are deposited, increasing the chance of pinhole and/or defect formation during treatment steps. Oleic acid also has a significantly higher boiling point than pyridine and it is likely that the residual carbon content in a cell made from oleic-acid capped CdTe will be higher.

Oleic acid can be readily exchanged with a shorter ligand such as hexylamine by adding a small amount of the amine to a precipitated sample of CdTe NCs. In this instance the CdTe were then suspended in chlorobenzene for deposition. As for the device made using oleic acid capped CdTe, this results in modest performance due to relatively low Voc and FF (FIG. 34(b)). It should be noted that altering the surface chemistry of the nanocrystals may alter their growth and oxidation rates during the sintering step. With further optimization it is likely that the performance of these devices will be increased.

### Influence of Device Architecture

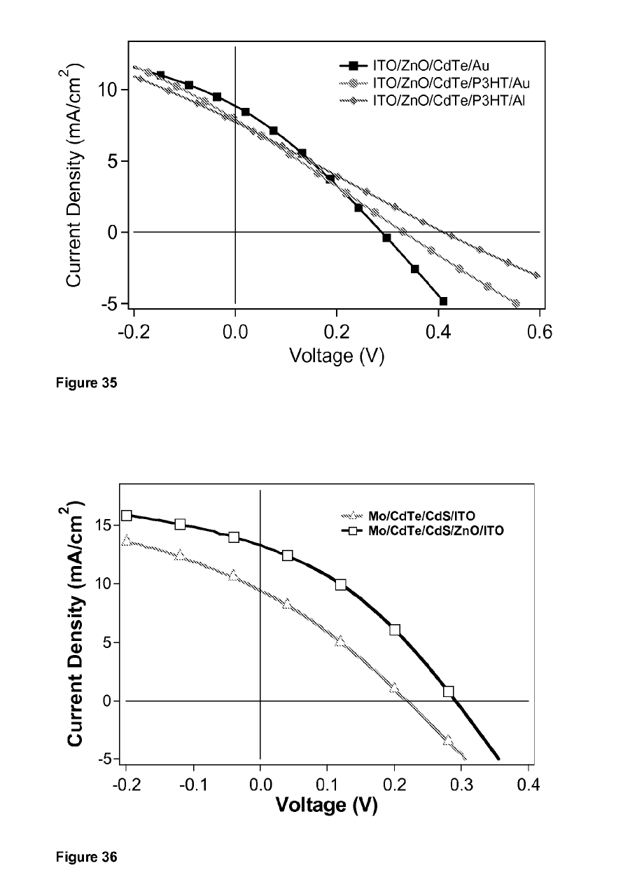

In the devices of the invention, illumination occurs through the absorbing CdTe layer with the transparent ZnO layer at the back of the device. This device architecture is reversed compared to traditional thin-film solar cells. In these latter device configurations, the majority of the light is absorbed near the interface between the two semiconductors. This maximizes the field for separating and collecting free charges. However, attempts to invert the device structures of the invention have so far shown limited success (FIG. 35 and Table VIII).

TABLE VIII
Performance characteristics for inverted device structures

| Structure | J_{sc} (mA/cm²) | V_{oc} (V) | FF | PCE (%) |
|---|---|---|---|---|
| ITO/ZnO/CdTe/Au | 8.85 | 0.29 | 0.29 | 0.74 |
| ITO/ZnO/CdTe/P3HT/Au | 7.91 | 0.34 | 0.25 | 0.67 |
| ITO/ZnO/CdTe/P3HT/Al | 8.26 | 0.37 | 0.26 | 0.79 |

It is possible that this inverted structure may lead to better performance in the future upon further optimization. It should be noted that the devices of the invention differ from traditional thin-film devices in that they are much thinner. It is possible that with such a thin absorbing layer, minority carriers are able to flow easily to the CdTe/ZnO interface with little recombination. However, it is also worth noting that although CdTe is a p-type material, the mobility of electrons is much higher than that of holes. In the standard device architecture, significant absorption occurs near the ITO/CdTe interface. This implies that holes only need to diffuse a short distance to be collected by the ITO, while electrons will on average need to traverse significantly further. If the device structure is inverted, the holes now must travel further without recombining. Because the hole mobility is in fact the limiting mobility in the CdTe, this can be detrimental if the CdTe thickness is too high.

An additional concern for these inverted devices is that it is difficult to form an ohmic contact to CdTe. This is because CdTe has a work function which is deeper than most electrode materials. In bulk CdTe solar cells an ohmic contact is often obtained by using Mo. This has been attempted by fabricating devices in the substrate configuration, using Mo-coated glass as the substrate. The device structures for these cells were Mo/CdTe/CdS/ZnO/ITO or Mo/CdTe/CdS/ITO. Performance results using this architecture have so far been relatively low (FIG. 36). It is worth noting that no efforts have been made to optimize cells made using this geometry, however the demonstration of working devices validates the applicability of our approach to substrate based device architectures.

### Influence of Absorbing Layer Composition

So far the effectiveness of layer-by-layer deposition for solar cells using a CdTe absorbing layer has been demonstrated. In reality, the layer-by-layer process is suitable to any semiconducting material that can be solution processed. To demonstrate this cells incorporating another II-VI semiconductor, CdSe were investigated. The CdSe was incorporated into the cells in two different manners, as pure CdSe layers and through alloying with CdTe.

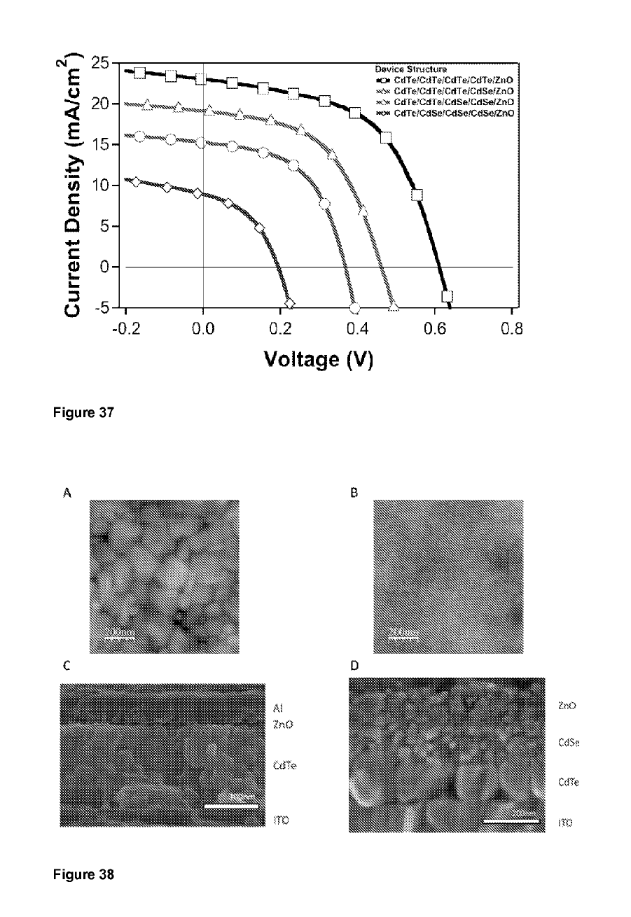

Firstly, the results of cells which incorporate discrete CdSe layers are presented. As mentioned above, previous reports on sintered nanocrystal solar cells have examined CdTe/CdSe systems using nanorods. In our approach only spherical nanocrystals are used. The device structures consists CdTe/CdSe/ZnO, all deposited in a layer-by-layer fashion. In FIG. 37 and Table IX the results are shown for cells in with differing number of CdTe and CdSe layers and therefore thicknesses. In total, 4 CdX (X=Se,Te) were deposited, with a total thickness of ˜400 nm. Following deposition of the CdX layers a 60 nm ZnO layer was deposited and finally an Al back contact.

TABLE IX
Performance results for CdTe/CdSe/ZnO solar cells.

| Device Structure | J_{sc} (mA/cm²) | V_{oc} (V) | FF | PCE |
|---|---|---|---|---|
| CdTe(400 nm)/ZnO | 22.6 | 0.61 | 0.53 | 7.3% |
| CdTe(300 nm)/CdSe(100 nm)/ZnO | 18.8 | 0.46 | 0.52 | 4.5% |
| CdTe(200 nm)/CdSe(200 nm)/ZnO | 15.2 | 0.37 | 0.52 | 2.9% |
| CdTe(100 nm)/CdSe(300 nm)/ZnO | 9.4 | 0.19 | 0.41 | 0.7% |

These results demonstrate a decrease in cell performance with increasing CdSe thickness. The best performing cell, which contains no CdSe yields a PCE of 7.3%. The best performing CdSe containing cell has a PCE of 4.5%. Although much lower than the CdTe-only cell this value represents the highest PCE reported to date for a CdTe/CdSe system. When the CdTe thickness is reduced to only 100 nm the cell performance is quite poor, 0.7%. When attempted were made to make a cell with no CdTe and only CdSe/ZnO, no photovoltaic performance was observed.

There are several possible explanations for the decrease in solar cell performance with increasing CdSe content. The annealing temperatures used in this study, 350° C., do induce some grain growth in CdSe films (FIG. 38) but the resulting crystallites are significantly smaller than for CdTe films which have received an equivalent treatment. This increases the number of grain boundaries in the film and may result in the formation of bound excitons rather than free charges for photons absorbed in the CdSe layer. This will result in increased charge recombination within the device. CdSe is also generally an n-type material with lower conductivity and doping density than ZnO. The former may hinder charge transport through the CdSe layers while the latter will reduce the width of the depletion region within the cell.

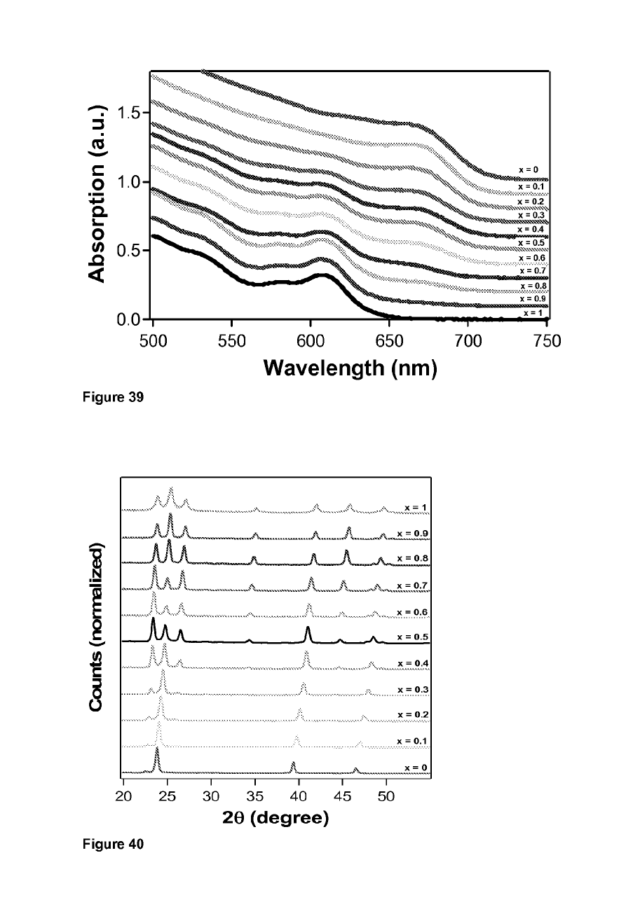

Having examined cells with discrete CdTe and CdSe layers we now turn to cells which incorporate alloyed layers of these two materials, denoted CdSexTe1-x. This was accomplished by separately synthesizing CdTe and CdSe nanocrystals of approximately 4.5 nm diameter. The as-synthesized nanocrystals were ligand exchanged with pyridine and then mixed together in a solution of pyridine:1-propanol at the desired ratio. Concentrations were determined by drying a known volume on nanoparticle ink to dryness. The absorption spectra of these CdSex:CdTe1-x solutions show that with increasing values of ‘x’ there is an increase in the intensity of the CdSe first excitonic peak centred at ˜609 nm and a decrease in the CdTe peak, centred at ˜670 nm (FIG. 39).

It should be noted that CdSexTe(1-x) nanocrystal alloys can be synthesized directly in solution. However, for some alloy materials this may not be possible. Therefore, the approach of synthesizing the nanocrystals separately and then combining them in a common solvent provides a more general method for achieving the desired alloy compositions. Thus, in general, in the method of the present application, the nanoparticles dispersion may comprise a solution of pre-synthesized nanocrystal alloy particles. In another embodiment, the nanoparticles dispersion may comprise a solution of nanocrystal alloy particles synthesized in situ to produce the nanoparticles dispersion.

The CdSex:CdTe1-x solutions were coated onto a substrate and subjected to CdCl2 and thermal treatment to yield CdSexTe1-x thin-films. XRD measurements were made to determine the crystal structure of the annealed films (FIG. 40). There is clear evidence of alloying with diffraction peaks shifting to higher 2 theta values with increasing values of x. The XRD pattern of CdTe agrees well with that of cubic phase CdTe, while the CdSe is consistent with the hexagonal phase. At x=0.1-0.2 it appears that there is still only cubic phase present. However, from x=0.3-0.7 there is evidence of both hexagonal and cubic phases. This co-existence of phases in CdSexTe1-x alloys has been reported previously in the art. At higher Se content, x=0.8-0.9 a small amount of cubic phase may be present but it appears that the crystal structure is almost entirely hexagonal.

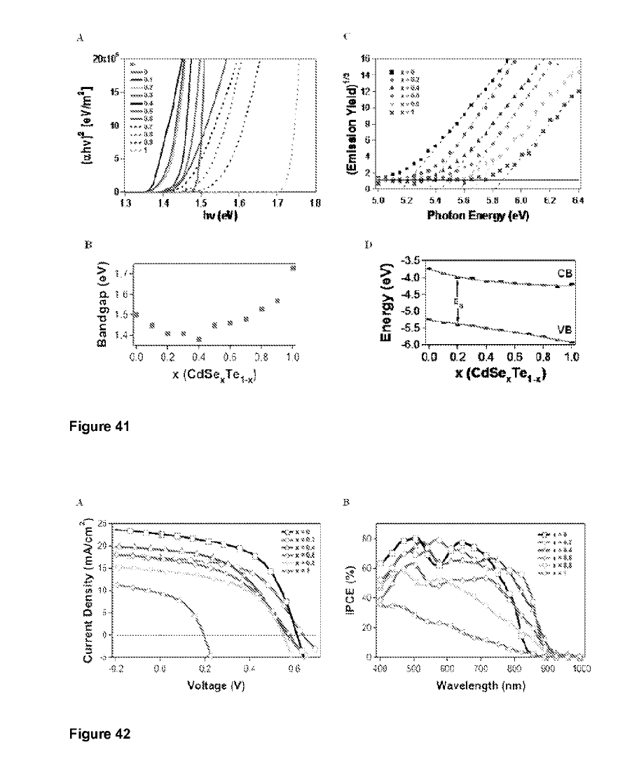

Alloys of CdSexTe1-x are known to exhibit ‘bandgap bowing’. This effect causes the bandgap of an alloyed semiconductor film to be smaller than either of its unalloyed components. The physical reason for this effect is the disorder caused by the presence of multiple anions (cations) in the crystal lattice. To examine the effects of bandgap bowing in our alloyed films absorbance measurements on CdSexTe1-x films were performed where the value of x has been varied from 0 to 1. From these results the optical bandgap from the linear region of a plot of (αhv)2 vs. hv can be determined. As seen in FIG. 41(A-B) these films clearly exhibit bandgap bowing, with a minimum of 1.38 eV when x=0.4, consistent with previous reports.

Along with the bandgap of an alloy structures it is desirable to know at what energies the valence band maxima and conduction band minima reside. This can be accomplished through the use of PESA measurements, which can used to determine the ionization potential of thin-films. This allowed us to establish the energy of the valence band maxima (FIG. 41C). This data was then combined with optical bandgap measurements to establish the conduction band maxima. The resulting energy levels are depicted in FIG. 41D.

The optical properties of a semiconductor are directly related to its spectral response in a solar cell. Although the bandgap of CdTe is nearly ideal for a single-junction solar cell it may be desirable to extend its spectral response in structures such as a tandem solar cell. The use of alloys to extend spectral response could also be desirable in materials where the bandgap of the pure semiconductor is not ideal for solar cell applications. To measure the spectral response of solar cells using CdSexTe1-x layers devices with the structure ITO/CdTe(100 nm)/CdSexTe1-x (300 nm)/ZnO/AI were made. The use of a pure CdTe layer ensures that differences in device performance are due to changes in the semiconducting layers and not the ITO/semiconductor interface. These cells showed PV performance with x varied from 0 to 1 (FIG. 42, Table X).

TABLE X
Performance results for CdTe/CdSeₓTe₍₁₋ₓ₎/ZnO solar cells
with x varied from 0 to 1.

| | J_{sc} | | | |
|---|---|---|---|---|
| Device Structure | (mA/cm²) | V_{oc} (V) | FF | Efficiency |
| CdTe(400 nm)/ZnO | 22.6 | 0.61 | 0.53 | 7.3% |
| CdTe(100 nm)/ | 20.3 | 0.61 | 0.57 | 7.1% |
| CdSe_{0.1}Te_{0.9}(300 nm)/ZnO | | | | |
| CdTe(100 nm)/ | 21.6 | 0.64 | 0.51 | 7.0% |
| CdSe_{0.2}Te_{0.8}(300 nm)/ZnO | | | | |
| CdTe(100 nm)/ | 19.5 | 0.63 | 0.47 | 5.8% |
| CdSe_{0.3}Te_{0.7}(300 nm)/ZnO | | | | |
| CdTe(100 nm)/ | 18.7 | 0.57 | 0.46 | 4.9% |
| CdSe_{0.4}Te_{0.6}(300 nm)/ZnO | | | | |
| CdTe(100 nm)/ | 16.0 | 0.56 | 0.49 | 4.4% |
| CdSe_{0.5}Te_{0.5}(300 nm)/ZnO | | | | |
| CdTe(100 nm)/ | 16.7 | 0.58 | 0.44 | 4.2% |
| CdSe_{0.6}Te_{0.4}(300 nm)/ZnO | | | | |
| CdTe(100 nm)/ | 15.2 | 0.59 | 0.54 | 4.8% |
| CdSe_{0.7}Te_{0.3}(300 nm)/ZnO | | | | |
| CdTe(100 nm)/ | 14.0 | 0.55 | 0.49 | 3.8% |
| CdSe_{0.8}Te_{0.2}(300 nm)/ZnO | | | | |
| CdTe(100 nm)/ | 11.9 | 0.49 | 0.42 | 2.5% |
| CdSe_{0.9}Te_{0.1}(300 nm)/ZnO | | | | |
| CdTe(100 nm)/ | 9.4 | 0.19 | 0.41 | 0.7% |
| CdSe(300 nm)/ZnO | | | | |

The highest device performance is seen for devices with only CdTe, with a consistent decline in PCE with increasing Se content. This could be due to a number of factors including: limited grain growth in films with higher Se, an unfavourable change in doping density or the transition of CdSeₓTe₁₋ₓ from p-type to n-type.

The spectral response of selected devices are shown in FIG. 42(b). For devices with only CdTe the spectral response drops to zero at wavelengths beyond ˜850 nm, consistent with the 1.5 eV bandgap of CdTe. For devices containing CdSeₓTe₁₋ₓ alloy films the spectral response clearly extends to longer wavelengths, as far as ˜900 nm. This shows that not only are lower energy photons absorbed in CdSeₓTe₁₋ₓ films but that they are also collected as photocurrent. At some alloy compositions the spectral response extends beyond the measured bandgap. This may be due to some intermixing of the CdTe and CdSeₓTe₁₋ₓ layers, leading to areas where the Se and Te content is varied from the nominal amounts.

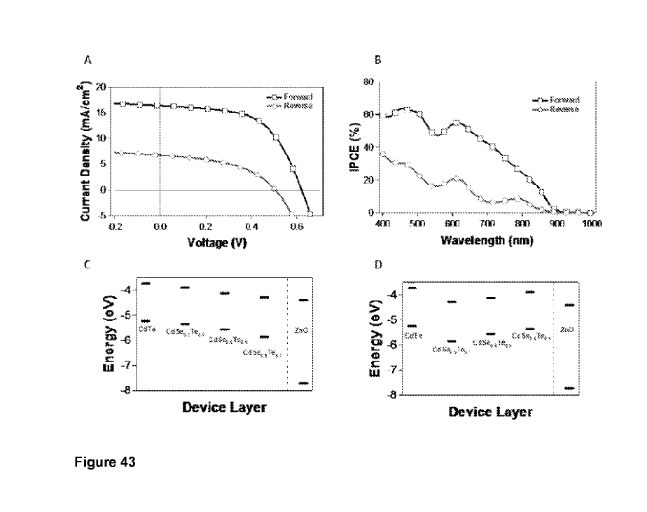

In some instances it may be desirable to have a gradient in alloy composition across the device. In this case it is possible to create an energy level cascade which is favourable for the transport of both holes and electrons. The layer-by-layer method is particularly well suited for accomplishing this device architecture. To accomplish this devices have been made with the structure ITO/CdTe/CdSe_{0.1}Te_{0.9}/CdSe_{0.5}Te_{0.5}/CdSe_{0.9}Te_{0.1}/ZnO/Al. In this ‘forward’ device structure the energy levels will promote the flow of charges between layers. Devices with the structure ITO/CdTe/CdSe_{0.9}Te_{0.1}/CdSe_{0.5}Te_{0.5}/CdSe_{0.1}Te_{0.9}/ZnO/Al have also been made. In this ‘reverse’ structure the energy levels show that charge transport through the device should be impeded. The results for these devices are shown in FIG. 43 and summarized in Table XI. The ‘forward’ structure exhibits much better performance, largely due to a higher Jsc value. This indicates that charge transport through this device is much better than for the ‘reverse’ device.

TABLE XI
Performance results for the graded alloy solar cells.

| Device | | | | |
|---|---|---|---|---|
| Structure | J_{sc} (mA/cm²) | V_{oc} (V) | FF | Efficiency |
| Forward | 15.5 | 0.62 | 0.56 | 5.4% |
| Reverse | 6.5 | 0.50 | 0.46 | 1.5% |

Thus, in one embodiment, the multilayer film of an inorganic material in the device or solar cell comprises a gradient of alloyed nanoparticles. For example, the multilayer film may comprise an increasing amount of one or more alloying elements in adjacent layers of the film. As another example, the multilayer film may comprise a decreasing amount of one or more alloying elements in adjacent layers of the film.

### Comparative Example

A Multilayer Film Compared with a Single Layer Film

CdTe/ZnO solar cells were fabricated in which CdTe was deposited either in a layer-by-layer fashion, as per the present invention, or as a single layer. For each type of device a number of different thicknesses were investigated.

For the layer-by-layer cells, each CdTe layer was treated with CdCl₂ and annealed at 350° C. for 15 s. For the single layer cells the CdTe film was CdCl₂ treated and annealed at 350° C. for 1 minute. A ˜55 nm thick layer of ZnO was then deposited and annealed at 300° C. for 2 minutes for both types of cells.

As shown in Table VII, all layer-by-layer cells demonstrated photovoltaic performance and efficiencies of >6% were recorded for CdTe thicknesses in the range 260-500 nm. In contrast, all cells with a single CdTe layer failed due to electrical shorting.

AFM imaging reveals that layer-by-layer films are uniform throughout while single layer films exhibit large pinholes, spanning the entire thickness of the CdTe layer, approximately 250 nm (see FIG. 26). These pinholes allow the two electrodes to come into direct contact, creating a short-circuit.

TABLE VII
Performance conversion efficiencies for CdTe/ZnO solar cells of
varying CdTe thickness in which the CdTe has either been
deposited in a layer-by-layer fashion (first two columns) or as a
single layer (final two columns).

| Layer-by-layer (4 layers) | | Single Layer | |
|---|---|---|---|
| CdTe thickness (nm) | PCE (%) | CdTe Thickness (nm) | PCE (%) |
| 90 | 2.2 | 93 | 0.00 |
| 105 | 4.4 | 173 | 0.00 |
| 260 | 6.6 | 233 | 0.00 |
| 400 | 6.9 | 374 | 0.01 |
| 500 | 6.3 | 421 | 0.02 |

The results in Table VII also provide a comparison of different CdTe layer thicknesses, establishing that for the layer-by-layer technique the optimal CdTe thickness is >200 nm.

The results in Table VII also show that in order to obtain photovoltaic performance from spherical particles the method of the invention can be used, as all devices made using a single layer failed. To obtain efficient cells from a single layer the use of nanorods is required due to the larger volume fraction they are able to occupy. Conversely, the method of the invention is applicable to particles of any shape, including rods.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1. A method for the production of an inorganic film on a substrate, the method comprising:
(a) depositing a layer of nanoparticles on the substrate by contacting the substrate with a nanoparticle dispersion;
(b) treating the deposited layer of nanoparticles to prevent removal of the nanoparticles in subsequent layer depositing steps;
(c) depositing a further layer of nanoparticles onto the preceding nanoparticle layer on the substrate;
(d) repeating treatment step (b) and deposition step (c) at least one further time; and
(e) optionally thermally annealing the multilayer film produced following steps (a) to (d);
wherein the method comprises at least one thermal annealing step in which the layer or layers of nanoparticles are thermally annealed to provide sintering between nanoparticles in adjacent layers of the film.

2. The method according to claim 1, wherein the nanoparticles are active material forming nanoparticles.

3. The method according to claim 2, wherein the active material forming nanoparticles are nanoparticles for forming a semiconductor material.

4. The method according to claim 1, wherein the nanoparticles comprise at least one element selected from the group consisting of group IB, IIB, IIIA, IVA, VA and VIA elements.

5. The method according to claim 1, wherein the nanoparticles comprise inorganic materials selected from the group consisting of silicon, amorphous silicon, copper, copper selenide, copper sulphide, copper telluride, copper indium sulphide, copper indium selenide, copper indium telluride, copper iron sulphide, copper indium gallium selenide, copper zinc tin sulphide, zinc oxide, zinc sulphide, zinc selenide, zinc telluride, zinc indium oxide, zinc gallium oxide, zinc aluminium oxide, zinc indium selenide, zinc gallium selenide, zinc aluminium selenide, zinc tin oxide, zinc tin sulphide, zinc tin selenide, zinc tin telluride, zinc tin gallium oxide, zinc tin gallium sulphide, zinc tin gallium selenide, zinc tin gallium telluride, tin oxide, tin sulphide, indium oxide, indium tin oxide, indium phosphide, indium sulphide, indium selenide, indium oxide, indium arsenide, cadmium selenide, cadmium telluride, cadmium sulphide, cadmium-tellurium selenide, cadmium oxide, lead selenide, lead sulphide, gallium oxide, gallium arsenide, gallium indium arsenide, gallium phosphide, iron sulphide, aluminium oxide, molybdenum trioxide, molybdenum dioxide, molybdenum trisulphide, molybdenum disulphide, molybdenum triselenide, molybdenum diselenide, nickel oxide, germanium, and mixtures, alloys or composites thereof.

6. The method according to claim 1, wherein the nanoparticles are cadmium telluride nanoparticles.

7. The method according to claim 1, wherein the nanoparticle dispersion comprises two or more different inorganic materials which upon thermal annealing form an active layer of a single composition.

8. (canceled)

9. The method according to claim 1, wherein the nanoparticles have a diameter up to about 100 nanometres.

10. The method according to claim 1, wherein the nanoparticles have a diameter of at least about 1 nanometre.

11. (canceled)

12. The method according to claim 1, wherein the nanoparticles are deposited in a thickness of at least about 25 nanometres.

13. The method according to claim 1, wherein the thickness of the inorganic film is between about 90 nanometres and about 3 microns.

14. (canceled)

15. The method according to claim 1, wherein the nanoparticles are dispersed in a solvent.

16. The method according to claim 1, wherein the deposition is solution processing performed by spin coating, dip-coating, printing, ink jet printing, gravure printing, spray-coating, doctor blading or slot-die coating.

17. The method according to claim 1, wherein the nanoparticle dispersion contains one or more additives, selected from the group consisting of salts, fillers, ligands, dopants and mixtures thereof.

18. (canceled)

19. The method according to claim 1, wherein at least one of the treatment steps (b) comprises a chemical treatment.

20. The method according to claim 19, wherein the chemical treatment comprises contacting the layer of nanoparticles with a solution comprising one or more chemical treatment agents selected from the group consisting of salts, fillers, ligands, dopants and mixtures thereof.

21. The method according to claim 19, wherein the chemical treatment comprises contacting the layer of nanoparticles with a surface modifier, selected from the group comprising of CdCl2 salts, ZnCl2 salts and CdBr2 salts .

22-23. (canceled)

24. The method according to claim 1, wherein the substrate on which the layer of nanoparticles is deposited in step (a) comprises a pre-deposited sol-gel layer or sol-gel produced inorganic film.

25. The method according to claim 1, wherein the method further comprises producing a second inorganic film on a first inorganic film produced by steps (a) to (e).

26. The method of claim 25, wherein the second inorganic film is produced by steps (f) to (j), as follows:
(f) depositing a layer of nanoparticles on the first inorganic film by contacting the first inorganic film with a nanoparticle dispersion;
(g) treating the deposited layer of nanoparticles to prevent removal of the nanoparticles in subsequent layer depositing steps;
(h) depositing a further layer of nanoparticles onto the preceding nanoparticle layer on the first inorganic film;
(i) repeating treatment step (g) and deposition step (h) at least one further time; and
(j) optionally thermally annealing the multilayer film produced following steps (f) to (i),
or by contacting the first inorganic film with a sol-gel, or by sputtering.

27-38. (canceled)
